(19) United States
(12) Patent Application Publication
(10) Pub. No.: US 2024/0429210 A1
(43) Pub. Date: Dec. 26, 2024

(54) DISPLAY DEVICE

(71) Applicant: SAMSUNG DISPLAY CO., LTD., YONGIN-SI (KR)

(72) Inventors: Ji Wook MOON, YONGIN-SI (KR); Ju Yon LEE, YONGIN-SI (KR); Jong Moo HUH, YONGIN-SI (KR); Min Woo KIM, YONGIN-SI (KR)

(21) Appl. No.: 18/658,562

(22) Filed: May 8, 2024

(30) Foreign Application Priority Data
Jun. 21, 2023 (KR) 10-2023-0079379

(51) Int. Cl. H01L 25/075; H01L 33/38; H01L 33/40; H01L 33/50

(52) U.S. Cl. CPC H01L 25/0753; H01L 33/38; H01L 33/405; H01L 33/505

(57) ABSTRACT

A display device includes a substrate, a plurality of pixel electrodes disposed on the substrate and spaced apart from each other at a first interval and a plurality of light emitting elements respectively disposed on the plurality of pixel electrodes. Each of the pixel electrodes has a rectangular shape having a long side and a short side, and a width of each of the light emitting elements is larger than a width of the short side and smaller than the first interval between the pixel electrodes.

### CROSS-REFERENCE TO RELATED APPLICATION

This patent application claims priority under 35 U.S.C. 119 to Korean Patent Application No. 10-2023-0079379 filed on Jun. 21, 2023 in the Korean Intellectual Property Office, the disclosure of which is incorporated by reference in its entirety herein.

### 1. TECHNICAL FIELD

The present disclosure is directed to a display device.

### 2. DISCUSSION OF RELATED ART

The importance of display devices has steadily increased with the development of multimedia technology. Examples of the display devices include an organic light emitting display (OLED) and a liquid crystal display (LCD).

A display device is a device for displaying an image, and includes a display panel, such as an organic light emitting display panel or a liquid crystal display panel. The light emitting display panel may include light emitting elements such as light emitting diodes (LED). Examples of the light emitting diode include an organic light emitting diode (OLED) using an organic material as a light emitting material and an inorganic light emitting diode using an inorganic material as a light emitting material. The display panel includes several pixels, where each pixel may include a pixel electrode and the light emitting element.

However, some of the light emitting elements may collapse due to an arrangement or shape of the pixel electrodes. Thus, light output efficiency of the light emitting elements may be low and reduce image quality.

### SUMMARY

Aspects of the present disclosure provide a display device and a manufacturing method thereof capable of preventing defects caused by collapse of light emitting elements when they are arranged on a pixel electrode.

According to an embodiment, a display device includes a substrate, a plurality of pixel electrodes, and a plurality of light emitting elements. The plurality of pixel electrodes are disposed on the substrate and spaced apart from each other at a first interval. The plurality of light emitting elements are respectively disposed on the plurality of pixel electrodes. Each of the pixel electrodes has a rectangular shape having a long side and a short side. A width of each of the light emitting elements is larger than a width of the short side and smaller than the first interval between the pixel electrodes.

In an embodiment, each of the light emitting elements includes a second semiconductor layer; an active layer disposed on the second semiconductor layer; and a first semiconductor layer disposed on the active layer, and a width of the first semiconductor layer is larger than the width of the short side and smaller than the first interval between the pixel electrodes.

In an embodiment, each of the light emitting elements further includes a connection electrode disposed on the first semiconductor layer and connected to the pixel electrode, and a width of the connection electrode is larger than the width of the short side of a corresponding one of the pixel electrodes and smaller than the first interval between the pixel electrodes.

In an embodiment, the width of each of the light emitting elements ranges from 8 μm to 16 μm.

In an embodiment, a length of the short side of each of the pixel electrodes ranges from 6 μm to 8 μm, a length of the long side of each of the pixel electrodes ranges from 45 μm to 55 μm, and the first interval ranges from 16 μm to 19 μm.

The display device may further include a first planarization layer disposed between the pixel electrodes.

The one pixel electrode may include a pixel reflective layer disposed in contact with the light emitting element.

The pixel reflective layer may have a reflectivity of 80% or more.

In an embodiment, the number of the light emitting elements disposed on the one pixel electrode is three, the light emitting elements disposed on the pixel electrode are spaced apart from each other at a second interval, and the second interval ranges from 10 μm to 20 μm.

In an embodiment, the number of the light emitting elements disposed on the one pixel electrode is two, the light emitting elements disposed on the one pixel electrode are spaced apart from each other at a second interval, and the second interval ranges from 15 μm to 20 μm.

In an embodiment, the number of the light emitting elements disposed on the one pixel electrode is four, the light emitting elements disposed on the one pixel electrode are spaced apart from each other at a second interval, and the second interval ranges from 10 μm to 15 μm.

In an embodiment, the display device further includes a second planarization layer disposed on the first planarization layer and disposed between the light emitting elements and a common electrode disposed on the second planarization layer and the light emitting elements and a wavelength converter disposed on the common electrode, wherein the wavelength converter includes a partition wall partitioning emission areas and a non-emission area, a wavelength conversion layer disposed between the partition walls and overlapping the emission areas, a light blocking member disposed on the partition wall and color filters disposed on the wavelength conversion layer, wherein the light blocking member does not overlap the one pixel electrode.

According to an embodiment, a display device includes a substrate, a plurality of pixel electrodes, and plurality of light emitting elements. The plurality of pixel electrodes are disposed on the substrate and are spaced apart from each other at a first interval. The plurality of light emitting elements are respectively disposed on the plurality of pixel electrodes. Each of the pixel electrodes has a rectangular shape having a long side and a short side. A width of each of the light emitting elements is larger than a width of the short side. A ratio of a length of the short side to the first interval is 1:1.7 to 1:1.8.

In an embodiment, each of the light emitting elements includes a second semiconductor layer; an active layer disposed on the second semiconductor layer; and a first semiconductor layer disposed on the active layer, and a width of the first semiconductor layer is larger than the width of the short side and smaller than the first interval between the pixel electrodes.

In an embodiment, each of the light emitting elements further comprises a connection electrode disposed on the first semiconductor layer and connected to a corresponding one of the pixel electrodes, and a width of the connection electrode is larger than the width of the short side of the one pixel electrode and smaller than the first interval between the pixel electrodes.

In an embodiment, the width of each of the light emitting elements ranges from 8 μm to 16 μm, a length of the short side of the one pixel electrode ranges from 6 μm to 8 μm, a length of the long side of the one pixel electrode ranges from 45 μm to 55 μm, and the first interval ranges from 16 μm to 19 μm.

The display device may further include a first planarization layer disposed between the pixel electrodes on the substrate.

In an embodiment, the number of the light emitting elements disposed on the one pixel electrode is three, the light emitting elements disposed on the pixel electrode are spaced apart from each other at a second interval, and the second interval ranges from 10 μm to 20 μm.

In an embodiment, the number of the light emitting elements disposed on the one pixel electrode is two, the light emitting elements disposed on the one pixel electrode are spaced apart from each other at a second interval, and the second interval ranges from 15 μm to 20 μm.

In an embodiment, the number of the light emitting elements disposed on the one pixel electrode is four, the light emitting elements disposed on the one pixel electrode are spaced apart from each other at a second interval, and the second interval ranges from 10 μm to 15 μm.

In accordance with a display device according to an embodiment, a width of a light emitting element is smaller than a cross-sectional width of a pixel electrode so that a phenomenon, in which a light emitting element is biased to an edge of the pixel electrode in the pixel electrode and collapses, can be prevented.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to an embodiment;

FIG. 2 is a schematic layout view illustrating a circuit of a display substrate of the display device according to an embodiment;

FIG. 3 is an equivalent circuit diagram of one pixel of a display device according to an embodiment;

FIG. 4 is an equivalent circuit diagram of one pixel of a display device according to an embodiment;

FIG. 5 is an equivalent circuit diagram of one pixel of a display device according to an embodiment;

FIG. 6 is a cross-sectional view schematically illustrating a part of a display area of the display device of FIG. 1;

FIG. 7 is a plan view schematically illustrating a pixel electrode and a light emitting element of FIG. 6 according to an embodiment;

FIG. 8 is a plan view schematically illustrating a pixel electrode and a light emitting element of FIG. 6 according to an embodiment;

FIG. 9 is a plan view of a pixel electrode and a light emitting element according to an embodiment;

FIG. 10 is a plan view of a pixel electrode and a light emitting element according to an embodiment;

FIG. 11 is a plan view of a pixel electrode and a light emitting element according to an embodiment;

FIG. 12 is a flowchart illustrating a method of manufacturing a display device according to an embodiment; and

FIGS. 13 to 25 are views illustrating a method of manufacturing a display device according to an embodiment.

FIG. 26 is an example diagram schematically showing a virtual reality device including a display device according to an embodiment;

FIG. 27 is an example diagram schematically showing a smart device including a display device according to an embodiment;

FIG. 28 is a diagram of an example schematically showing a vehicle including a display device according to an embodiment; and

FIG. 29 is a diagram of an example schematically showing a transparent display device including a display device according to an embodiment.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side.

When an element is referred to as being “connected” or “coupled” to another element, the element may be “directly connected” or “directly coupled” to another element, or “electrically connected” or “electrically coupled” to another element with one or more intervening elements interposed therebetween.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Hereinafter, embodiments of the present disclosure will be described in detail with reference to the accompanying drawings.

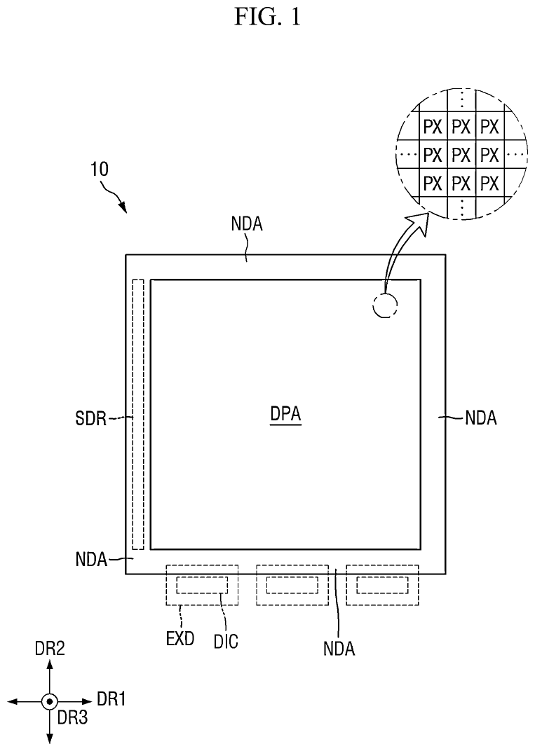

FIG. 1 is a plan view of a display device according to an embodiment.

Referring to FIG. 1, a display device 10 according to an embodiment may be applied to a smartphone, a mobile phone, a tablet PC, a personal digital assistant (PDA), a portable multimedia player (PMP), a television, a game machine, a wristwatch-type electronic device, a head-mounted display, a monitor of a personal computer, a laptop computer, a car navigation system, a car's dashboard, a digital camera, a camcorder, an external billboard, an electronic billboard, a medical device, an inspection device, various household appliances such as a refrigerator and a washing machine, or an Internet-of-Things device. Herein, a television (TV) is described as an example of a display device, and the TV may have a high resolution or an ultra high resolution such as high-definition (HD), ultra high-definition (UHD), 4K and 8K.

In addition, the display device 10 according to an embodiment may be classified into various types according to a display method. Examples of the display device 10 may include an organic light emitting display (OLED) device, an inorganic light emitting display (inorganic EL) device, a quantum dot light emitting display (QED) device, a micro-LED display device, a nano-LED display device, a plasma display device (PDP), a field emission display (FED) device, a cathode ray tube (CRT) display device, a liquid crystal display (LCD) device, an electrophoretic display (EPD) device, and the like. Hereinafter, the organic light emitting display device will be described as an example of the display device 10. However, embodiments of the disclosure are not limited to the organic light emitting display device, and other display devices mentioned above or known in the art may be applied within a same scope of the disclosure.

In addition, in the drawings, a first direction DR1 refers to a horizontal direction of the display device 10, a second direction DR2 refers to a vertical direction of the display device 10, and a third direction DR3 refers to a thickness direction of the display device 10. In this case, “left”, “right”, “upper” and “lower” refer to directions when the display device 10 is viewed from above. For example, “right side” refers to one side of the first direction DR1, “left side” refers to the other side of the first direction DR1, “upper side” refers to one side of the second direction DR2, and “lower side” refers to the other side of the second direction DR2. Further, “top” refers to one side of the third direction DR3, and “bottom” refers to the other side of the third direction DR3.

The display device 10 according to an embodiment may have a quadrate shape, e.g., a square shape in a plan view. In addition, when the display device 10 is a television, it may have a rectangular shape with a long side positioned in the horizontal direction. However, the present disclosure is not limited thereto, and the long side of the display device I may extend in a vertical direction. Alternatively, the display device 1 may be installed to be rotatable such that its long side is variably positioned to extend in the horizontal or vertical direction. Further, the display device 10 may have a circular shape or an elliptical shape.

The display device 10 may include the display area DPA and a non-display area NDA. The display area DPA may be an active area in which an image is displayed. The display area DPA may have a square shape in a plan view similar to the overall shape of the display device 10, but the present disclosure is not limited thereto.

The display area DPA may include a plurality of pixels PX. The plurality of pixels PX may be arranged in a matrix. The shape of each pixel PX may be rectangular or square in a plan view. However, each pixel PX may instead have a rhombic shape of which each side is inclined with respect to one side direction of the display device 10. The pixels PX may include multiple color pixels PX. For example, the pixels PX may include, a first color pixel PX of red, a second color pixel PX of green, and a third color pixel PX of blue, although not limited thereto. The color pixels PX may be alternately arranged in a stripe type or a pentile™ type.

The non-display area NDA may be disposed around the display area DPA. The non-display area NDA may completely or partially surround the display area DPA. The display area DPA may have a square shape, and the non-display area NDA may be disposed adjacent to four sides of the display area DPA. The non-display area NDA may form a bezel of the display device 10.

In the non-display area NDA, a driving circuit or a driving element for driving the display area DPA may be disposed. In an embodiment, in the non-display area NDA disposed adjacent to a first side (lower side in FIG. 1) of the display device 10, a pad portion may be provided on a display substrate of the display device 10, and an external device EXD may be mounted on pad electrodes of the pad portion. The external device EXD may include, e.g., a connection film, a printed circuit board, a driver integrated circuit (DIC), a connector, a wiring connection film and the like. A scan driver SDR (e.g., a driver circuit) formed on the display substrate of the display device 10 may be provided in the non-display area NDA disposed adjacent to a second side (left side in FIG. 1) of the display device 10. The scan driver SDR may directly contact an upper surface of the display substate.

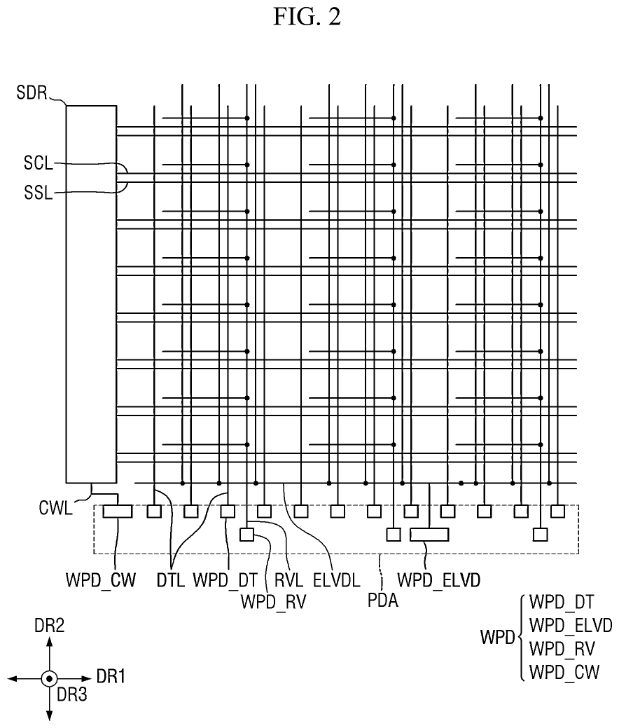

FIG. 2 is a schematic layout view illustrating a circuit of the display substrate of the display device according to an embodiment.

Referring to FIG. 2, a plurality of wirings are disposed on a first substrate of the display substate. In an embodiment, the plurality of wirings may include a scan line SCL, a sensing signal line SSL, a data line DTL, a reference voltage line RVL, and a first power line ELVDL.

The scan line SCL and the sensing signal line SSL may extend in a first direction DR1. The scan line SCL and the sensing signal line SSL may be connected to the scan driver SDR. The scan driver SDR may include a driving circuit. The scan driver SDR may be disposed on one side of the non-display area NDA on the display substrate, but the present disclosure is not limited thereto. For example, the scan driver SDR may be disposed on both sides of the non-display area NDA. The scan driver SDR is connected to a signal connection line CWL, and at least one end of the signal connection line CWL may form a pad WPD_CW on a first part of the non-display area NDA and/or a second part of the non-display area NDA which may be connected to the external devices (EXD in FIG. 1).

The data line DTL and the reference voltage line RVL may extend in a second direction DR2 crossing the first direction DR1. The first power line ELVDL may include portions extending in the second direction DR2. The first power line ELVDL may further include a portion extending in the first direction DR1. The first power line ELVDL may have a mesh structure, but the present disclosure is not limited thereto.

At least one end of the data line DTL, the reference voltage line RVL, and the first power line ELVDL may be provided with wiring pads WPD. Each wiring pad WPD may be provided in a pad portion PDA of the non-display area NDA. In an embodiment, a wiring pad WPD_DT (hereinafter, referred to as a ‘data pad’) of the data line DTL, a wiring pad WPD_RV (hereinafter, referred to as ‘reference voltage pad’) of the reference voltage line RVL, and a wiring pad WPD_ELVD (hereinafter, referred to as a ‘first power pad’) of the first power line ELVDL are disposed in the pad portion PDA of the non-display area NDA. In another example, the data pad WPD_DT, the reference voltage pad WPD_RV, and the first power pad WPD_ELVD may be disposed in another non-display area NDA. As described above, the external devices (‘EXD’ in FIG. 1) may be mounted on the wiring pads WPD. The external devices EXD may be mounted on the wiring pads WPD by applying an anisotropic conductive film, ultrasonic bonding or the like.

In an embodiment, each pixel PX on the display substrate includes a pixel driving circuit. The above-described wirings may pass through each pixel PX or the vicinity thereof to apply a driving signal to each pixel driving circuit. The pixel driving circuit may include transistors and capacitors. The number of the transistors and the capacitors of each pixel driving circuit may be variously modified. Hereinafter, the pixel driving circuit will be described in conjunction with a 3T1C structure including three transistors and one capacitor as an example. However, the present disclosure is not limited thereto, and other modified pixel PX structures such as a 2T1C structure, a 7T1C structure, and a 6T1C structure may be adopted.

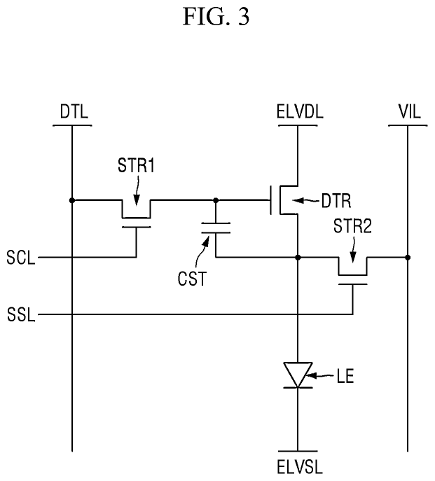

FIG. 3 is an equivalent circuit diagram of a pixel of the display area DPA of FIG. 1 according to an embodiment.

Referring to FIG. 3, each pixel PX of the display device according to an embodiment includes three transistors DTR, STR1 and STR2 and one storage capacitor CST in addition to a light emitting element LE.

The light emitting element LE emits light according to a current supplied through a driving transistor DTR. The light emitting element LE may be implemented as an inorganic light emitting diode, an organic light emitting diode, a micro light emitting diode, or a nano light emitting diode.

A first electrode (i.e., anode electrode) of the light emitting element LE is connected to a source electrode of the driving transistor DTR, and a second electrode (i.e., cathode electrode) of the light emitting element EMD is connected to a second power line ELVSL to which a low potential voltage (second source voltage) lower than a high potential voltage (first source voltage) of the first power line ELVDL is supplied.

The driving transistor DTR adjusts a current flowing from the first power line ELVDL, to which the first source voltage is applied, to the light emitting element LE according to a voltage difference between its gate electrode and its source electrode. The gate electrode of the driving transistor DTR may be connected to the first electrode of a first transistor ST1, the source electrode thereof may be connected to the first electrode of the light emitting element LE, and the drain electrode thereof may be connected to the first power supply line ELVDL to which the first power voltage is applied.

A first transistor STR1 is turned on by the scan signal of a scan line SCL to connect a data line DTL to the gate electrode of the driving transistor DTR. The gate electrode of the first transistor STR1 may be connected to the scan line SL, the first electrode thereof may be connected to the gate electrode of the driving transistor DTR, and the second electrode thereof may be connected to the data line DTL.

A second transistor STR2 is turned on by the sensing signal of a sensing signal line SSL to connect an initialization voltage line VIL to the source electrode of the driving transistor DTR. The gate electrode of the second transistor ST2 may be connected to the sensing signal line SSL, the first electrode thereof may be connected to the initialization voltage line VIL, and the second electrode thereof may be connected to the source electrode of the driving transistor DTR.

In an embodiment, the first electrode of each of the first and second transistors STR1 and STR2 is a source electrode and the second electrode thereof is a drain electrode, but the present disclosure is not limited thereto, and may be vice versa.

The capacitor CST is formed between the gate electrode and the source electrode of the driving transistor DTR. The storage capacitor CST stores a difference voltage between a gate voltage and a power voltage of the driving transistor DTR.

The driving transistor DTR, the first transistor STR1, and the second transistor STR2 may be thin film transistors. Further, in the description of FIG. 3, it is assumed that the driving transistor DTR, the first switching transistor STR1, and the second switching transistor STR2 are N-type metal oxide semiconductor field effect transistors (MOSFETs), but the present disclosure is not limited thereto. That is, the driving transistor DTR, the first switching transistor STR1, and the second switching transistor STR2 may be P-type MOSFETs, or some of the driving transistor DTR, the first switching transistor STR1, and the second switching transistor STR2 may be N-type MOSFETs, while others may be P-type MOSFETs.

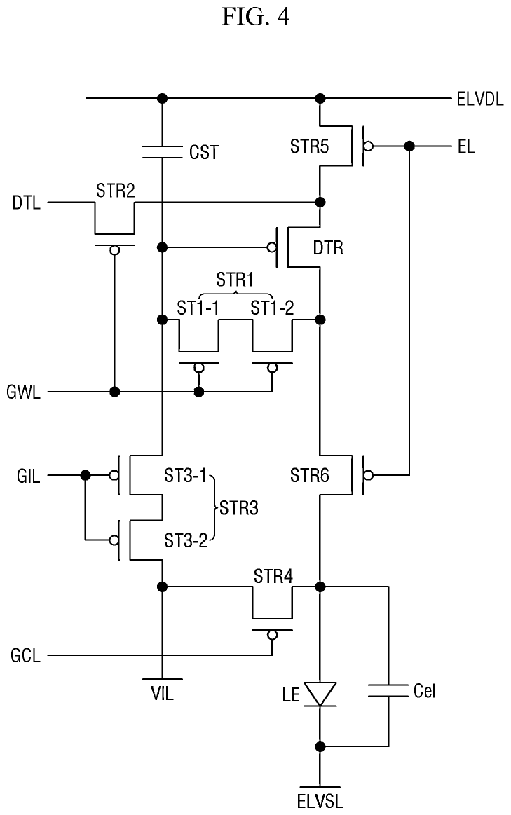

FIG. 4 is an equivalent circuit diagram of a pixel of the display area DPA of FIG. 1 according to an embodiment.

Referring to FIG. 4, the first electrode of the light emitting element LE may be connected to the first electrode of a fourth transistor STR4 and the second electrode of a sixth transistor STR6, and the second electrode thereof may be connected to the second power line ELVSL. A parasitic capacitance Cel may be formed between the first electrode and the second electrode of the light emitting element LE.

Each pixel PX includes the driving transistor DTR, switch elements, and the capacitor CST. The switch elements include first to sixth transistors STR1, STR2, STR3, STR4, STR5, and STR6.

The driving transistor DTR includes a gate electrode, a first electrode, and a second electrode. The driving transistor DTR controls a drain-source current Ids (hereinafter, referred to as “driving current”) flowing between its first electrode and its second electrode according to a data voltage applied to its gate electrode.

The capacitor CST is formed between the second electrode of the driving transistor DTR and a second power line ELVSL. One electrode of the capacitor CST may be connected to the second electrode of the driving transistor DTR, and the other electrode thereof may be connected to the second power line ELVSL.

When the first electrode of each of the driving transistor DTR and the first to sixth transistors STR1 to STR6 is a source electrode, the second electrode thereof may be a drain electrode. Alternatively, when the first electrode of each of the driving transistor DTR and the first to sixth transistors STR1 to STR6 is a drain electrode, the second electrode thereof may be a source electrode. In an embodiment, transistor STR1 may include a pair of transistors STR1-1 and STR1-2; and transistor STR3 may include a pair of transistors STR3-1 and STR3-2. An emission line EL connects gates of transistors STR5 and STR6.

An active layer of each of the driving transistor DTR and the first to sixth transistors STR1 to STR6 may be formed of any one of polysilicon, amorphous silicon, or an oxide semiconductor. When a semiconductor layer of each of the driving transistor DTR and the first to sixth transistors STR1 to STR6 is formed of polysilicon, a process for forming the semiconductor layer may be a low temperature polysilicon (LTPS) process.

Further, in FIG. 4, while the driving transistor DTR and the first to sixth transistors STR1 to STR6 may be formed of a p-type metal oxide semiconductor field effect transistor (MOSFET), they are not limited thereto since they may be formed of an n-type MOSFET.

Furthermore, a first power voltage of the first power line ELVDL, a second power voltage of the second power line ELVSL, and a third power voltage of a third power line VIL may be set in consideration of the characteristics of the driving transistor DTR, or the characteristics of the light emitting element LE.

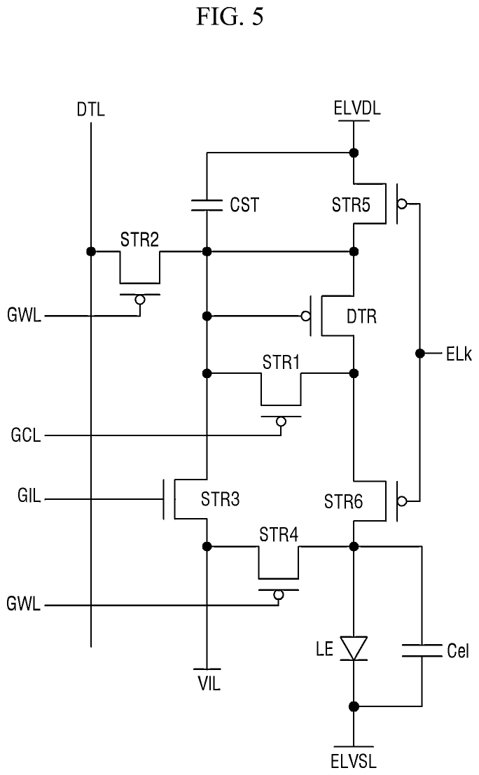

FIG. 5 is an equivalent circuit diagram of a pixel of the display area DPA of FIG. 1 according to an embodiment.

The embodiment of FIG. 5 is different from the embodiment of FIG. 4 in that the driving transistor DTR, the second transistor STR2, the fourth transistor STR4, the fifth transistor STR5, and the sixth transistor STR6 are formed as the P-type MOSFETs, and the first transistor STR1 and the third transistor STR3 are formed as the N-type MOSFETs.

Referring to FIG. 5, an active layer of each of the driving transistor DTR, the second transistor STR2, the fourth transistor STR4, the fifth transistor STR5 and the sixth transistor STR6 configured as the P-type MOSFETs may be formed of polysilicon, whereas an active layer of each of the first transistor STR1 and the third transistor STR3 configured as the N-type MOSFETs may be formed of an oxide semiconductor.

The embodiment of FIG. 5 is different from the embodiment of FIG. 4 in that the gate electrode of the second transistor STR2 and the gate electrode of the fourth transistor STR4 are connected to a write scan line GWL, and the gate electrode of the first transistor ST1 is connected to a control scan line GCL. Further, in FIG. 5, since the first transistor STR1 and the third transistor STR3 are formed of the N-type MOSFET, the scan signal of a gate high voltage may be applied to the control scan line GCL and an initialization scan line GIL. On the contrary, the second transistor STR2, the fourth transistor STR4, the fifth transistor STR5, and the sixth transistor STR6 are formed as the P-type MOSFETs, so that a scan signal of a gate low voltage may be applied to the write scan line GWL and an emission line ELk.

Meanwhile, it should be noted that the equivalent circuit diagram of the pixel according to the above-described embodiment of the present specification is not limited to those illustrated in FIGS. 3 to 5. The equivalent circuit diagram of the pixel according to the embodiment of the present specification may be formed in other known circuit structures that those skilled in the art may employ in addition to the embodiments illustrated in FIGS. 3 to 5.

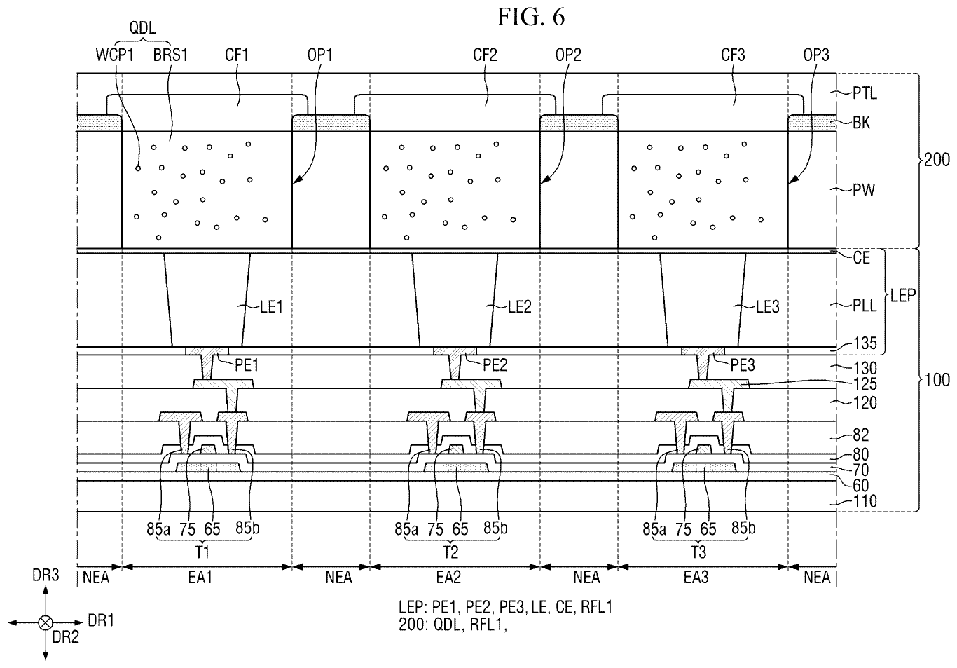

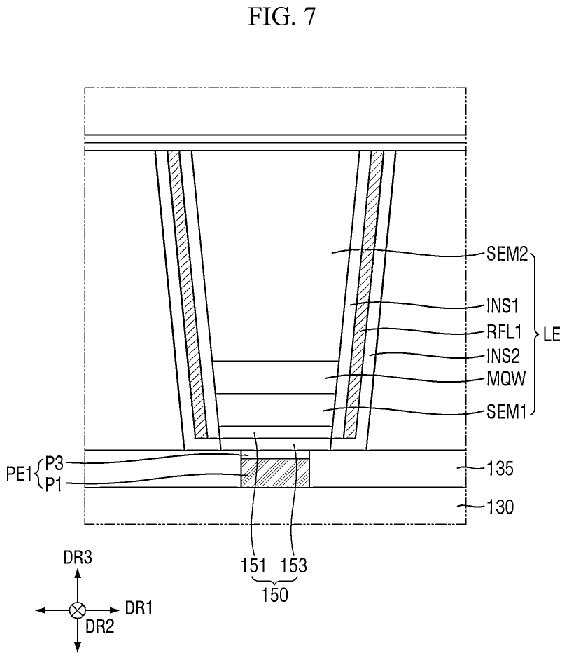

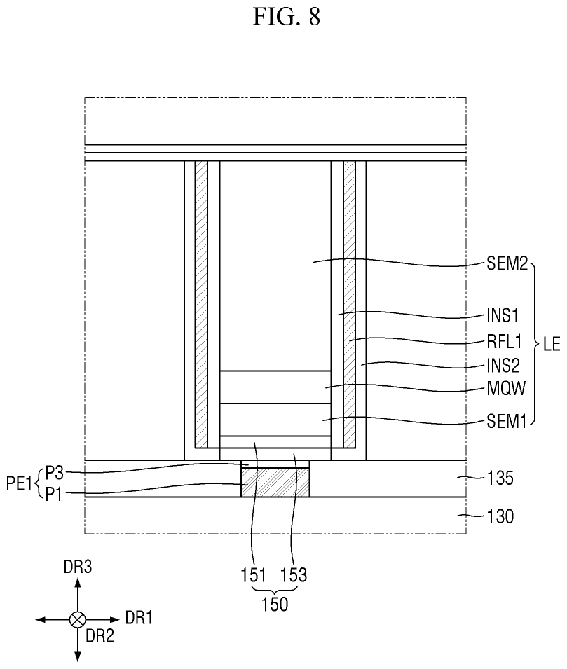

FIG. 6 is a cross-sectional view schematically illustrating a part of the display area DPA of the display device of FIG. 1. FIG. 7 is a plan view schematically illustrating a pixel electrode and a light emitting element of FIG. 6 according to an embodiment. FIG. 8 is a plan view schematically illustrating a pixel electrode and a light emitting element according to one embodiment.

Referring to FIG. 6, the display device 10 may include a display substrate 100 and a wavelength converter 200 disposed on the display substrate 100.

The display substrate 100 may include a first substrate 110 and a light emitting element unit LEP disposed on the first substrate 110. The first substrate 110 may be an insulating substrate. The first substrate 110 may include a transparent material. For example, the first substrate 110 may include a transparent insulating material such as glass, quartz, or the like. The first substrate 110 may be a rigid substrate. However, the first substrate 110 is not limited thereto. The first substrate 110 may include plastic such as polyimide or the like, and may have a flexible property such that it can be twisted, bent, folded, or rolled. A plurality of emission areas EA1, EA2, and EA3 and a non-emission area NEA may be defined in the first substrate 110. The non-emission area NEA may be provided in a plurality.

Switching elements T1, T2, and T3 may be positioned on the first substrate 110. In an embodiment, the first switching element T1 is positioned in the first emission area EA1 of the first substrate 110, the second switching element T2 is positioned in the second emission area EA2 thereof, and the third switching element T3 is positioned in the third emission area EA3 thereof. However, the present disclosure is not limited thereto. For example, in another embodiment, at least one of the first switching element T1, the second switching element T2 and the third switching element T3 may be located in the non-emission region NEA.

In one embodiment, each of the first switching element T1, the second switching element T2, and the third switching element T3 may be a thin film transistor including amorphous silicon, polysilicon, or an oxide semiconductor. In addition, a plurality of signal lines (e.g., a gate line, a data line, a power line, and the like) that transmit signals to the switching elements may be further positioned on the first substrate 110.

Each of the switching elements T1, T2, and T3 may include a semiconductor layer 65, a gate electrode 75, a source electrode 85a, and a drain electrode 85b. Specifically, a buffer layer 60 may be disposed on the first substrate 110. The buffer layer 60 may be disposed to cover the entire surface of the first substrate 110. The buffer layer 60 may include silicon nitride, silicon oxide, or silicon oxynitride, and may be formed as a single layer or a double layer thereof.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, or an oxide semiconductor. For example, the oxide semiconductor may include, for example, a binary compound (ABx), a ternary compound (ABxCy), or a quaternary compound (ABxCyDz) including indium, zinc, gallium, tin, titanium, aluminum, hafnium (Hf), zirconium (Zr), magnesium (Mg) and the like. In an embodiment, the semiconductor layer 65 includes indium tin zinc oxide (IGZO).

A gate insulating layer 70 may be disposed on the semiconductor layer 65. The gate insulating layer 70 may include a silicon compound, a metal oxide, or the like. For example, the gate insulating layer 70 may include silicon oxide, silicon nitride, silicon oxynitride, aluminum oxide, tantalum oxide, hafnium oxide, zirconium oxide, titanium oxide, or the like. In an embodiment, the gate insulating layer 70 includes silicon oxide.

The gate electrode 75 may be disposed on the gate insulating layer 70. The gate electrode 75 may be disposed to overlap the semiconductor layer 65. The gate electrode 75 may include a conductive material. The gate electrode 75 may include a metal oxide such as ITO, IZO, ITZO, and In₂O₃ or a metal such as copper (Cu), titanium (Ti), aluminum (Al), molybdenum (Mo), tantalum (Ta), calcium (Ca), chromium (Cr), magnesium (Mg), and nickel (Ni). For example, the gate electrode 75 may be formed as a Cu/Ti double layer in which an upper layer made of copper is stacked on a lower layer made of titanium, but the present disclosure is not limited thereto.

A first interlayer insulating layer 80 and a second interlayer insulating layer 82 may be disposed on the gate electrode 75. The first interlayer insulating layer 80 may be disposed on the gate electrode 75, and the second interlayer insulating layer 82 may be disposed on the first interlayer insulating layer 80. In an embodiment, the first interlayer insulating layer 80 directly contacts the gate electrode 75 and the second interlayer insulating layer 82 directly contacts the first interlayer insulating layer 80. Each of the first interlayer insulating layer 80 and the second interlayer insulating layer 82 may include an inorganic insulating material such as silicon oxide, silicon nitride, silicon oxynitride, hafnium oxide, aluminum oxide, titanium oxide, tantalum oxide, zinc oxide, or the like. However, the present disclosure is not limited thereto, and the second interlayer insulating layer 82 may include an organic insulating material capable of flattening a stepped portion disposed thereunder. Although two interlayer insulating layers of the first interlayer insulating layer 80 and the second interlayer insulating layer 82 have been illustrated and described in the present embodiment, the present disclosure is not limited thereto. For example, the first interlayer insulating layer 80 and the second interlayer insulating layer 82 may be replaced with a single interlayer insulating layer.

The source electrode 85a and the drain electrode 85b may be disposed on the second interlayer insulating layer 82. The source electrode 85a and the drain electrode 85b may be in contact with the semiconductor layer 65 through contact holes penetrating the first interlayer insulating layer 80, the second interlayer insulating layer 82, and the gate insulating layer 70. The source electrode 85a and the drain electrode 85b may include a metal oxide such as ITO, IZO, ITZO, and In₂O₃ or a metal such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be formed as a Cu/Ti double layer in which an upper layer made of copper is stacked on a lower layer made of titanium, but the present disclosure is not limited thereto.

A first planarization layer 120 may be disposed on the first switching element T1, the second switching element T2, and the third switching element T3. The first planarization layer 120 may include an organic material. For example, the first planarization layer 120 may include acrylic resin, epoxy resin, imide resin, ester resin, or the like. In an embodiment, the first planarization layer 120 may include a positive photosensitive material or a negative photosensitive material.

A pixel connection electrode 125 may be disposed on the first planarization layer 120. The pixel connection electrode 125 may be disposed to correspond to each of the first switching element T1, the second switching element T2, and the third switching element T3, and may be electrically connected thereto. For example, a separate pixel electrode 125 may be present for each of the first switching element T1, the second switching element T2, and the third switching element T3. The pixel connection electrode 125 may connect pixel electrodes PE1, PE2, and PE3 to be described below to the above-described switching elements T1, T2, and T3. The pixel connection electrode 125 may be in contact with the switching elements T1, T2, and T3 through contact holes penetrating the first planarization layer 120.

A second planarization layer 130 may be disposed on the first planarization layer 120 and the pixel connection electrode 125. The second planarization layer 130 may flatten a stepped portion disposed thereunder, and may include the same material as that of the above-described first planarization layer 120.

The light emitting element unit LEP may be disposed on the second planarization layer 130. The light emitting element unit LEP may include the plurality of pixel electrodes PE1, PE2, and PE3, the plurality of light emitting elements LE, and the common electrode CE.

The plurality of pixel electrodes PE1, PE2, and PE3 may include the first pixel electrode PE1, the second pixel electrode PE2, and the third pixel electrode PE3. The first pixel electrode PE1, the second pixel electrode PE2, and the third pixel electrode PE3 may serve as the first electrode of the light emitting element LE, and may be an anode electrode or a cathode electrode. The first pixel electrode PE1 may be located in the first emission area EA1, the second pixel electrode PE2 may be located in the second emission area EA2, and the third pixel electrode PE3 may be located in the third emission area EA3.

The first pixel electrode PE1 may penetrate the second planarization layer 130 to be connected to the first switching element T1, the second pixel electrode PE2 may penetrate the second planarization layer 130 to be connected to the second switching element T2, and the third pixel electrode PE3 may penetrate the second planarization layer 130 to be connected to the third switching element T3.

The pixel electrodes PE1, PE2, and PE3 may be directly connected to the pixel connection electrode 125 through the contact holes penetrating the second planarization layer 130, and may be electrically connected to the switching elements T1, T2, and T3 through the pixel connection electrode 125, respectively. The first pixel electrode PE1, the second pixel electrode PE2, and the third pixel electrode PE3 may include a metal. The metal may include, e.g., copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Further, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have a two-layer structure in which a copper layer is stacked on a titanium layer, but the present disclosure is not limited thereto. For example, the first pixel electrode PE1, the second pixel electrode PE2, and the third pixel electrode PE3 may have a two-layer structure in which a copper layer is stacked on a titanium layer, but the present disclosure is not limited thereto. Further, the first pixel electrode PE1, the second pixel electrode PE2, and the third pixel electrode PE3 may include a reflective layer coated with a reflective material.

In an embodiment, each of the pixel electrodes PE1, PE2, and PE3 include a pixel electrode layer P1 and a reflective layer P3. Hereinafter, the light emitting element LE disposed on the first pixel electrode PE1 will be described as an example in FIGS. 7 and 8, but the present disclosure is not limited thereto, and the light emitting elements LE disposed on the second pixel electrode PE2 and the third pixel electrode PE3 may have the same structure.

The pixel electrode layer P1 may be electrically connected to a switching element. The pixel electrode layer P1 may also serve to provide adhesion to a contact material between the second planarization layer 130 and the light emitting element LE. In an embodiment, the pixel electrode layer P1 is a single layer, but the pixel electrode layer P1 may have multiple metal layers in other embodiments. For example, the pixel electrode layer P1 may include a lower electrode layer containing titanium and an upper electrode layer containing copper.

A pixel reflective layer P3 may be disposed on the pixel electrode layer P1 and may be in direct contact with the light emitting element LE. The pixel reflective layer P3 may be disposed between the pixel electrode layer P1 and the light emitting element LE. The pixel reflective layer P3 may be formed by coating the pixel electrode layer P1 with a reflective material having a reflectivity of at least 80%. For example, the reflective material may be Ag, Ni, Cr, or the like.

In an embodiment, the pixel electrode layer P1 is formed to have the same width as the pixel reflective layer P3. Therefore, the pixel electrode layer P1 may completely overlap the pixel reflective layer P3 in the thickness direction (the third direction DR3).

Referring to FIGS. 6 and 8, a plurality of light emitting elements LE may be disposed on the first pixel electrode PE1, the second pixel electrode PE2, and the third pixel electrode PE3.

That is, the light emitting elements LE may be disposed in each of the first emission area EA1, the second emission area EA2, and the third emission area EA3. The light emitting element LE may be a vertical light emitting diode element elongated in the third direction DR3. That is, the length of the light emitting element LE in the third direction DR3 may be longer than the length thereof in the horizontal direction. The length in the horizontal direction refers to a length in the first direction DR1 or a length in the second direction DR2. For example, the length of the light emitting element LE in the third direction DR3 may be approximately 1 to 5 mm. However, the present disclosure is not limited thereto, and the length of the light emitting element LE in the third direction DR3 may also be equal to or smaller than the length in the horizontal direction.

Referring to FIGS. 7 and 8, the light emitting elements LE may have a cylindrical shape that is longer in width than in height, a disc shape, or a rod shape. However, the present disclosure is not limited thereto, and the light emitting element LE may have various shapes, such as a rod shape, a wire shape, a tube shape, a polygonal prism shape such as a regular cube, a rectangular parallelepiped and a hexagonal prism, or a shape extending in one direction and having a partially inclined outer surface.

The light emitting element LE may be a micro light emitting diode element. The light emitting element LE may include a connection electrode 150, a first semiconductor layer SEM1, an active layer MQW, and a second semiconductor layer SEM2 in the thickness direction of the display substrate 100, that is, in the third direction DR3. The connection electrode 150, the first semiconductor layer SEM1, the active layer MQW, and the second semiconductor layer SEM2 may be sequentially stacked in the third direction DR3.

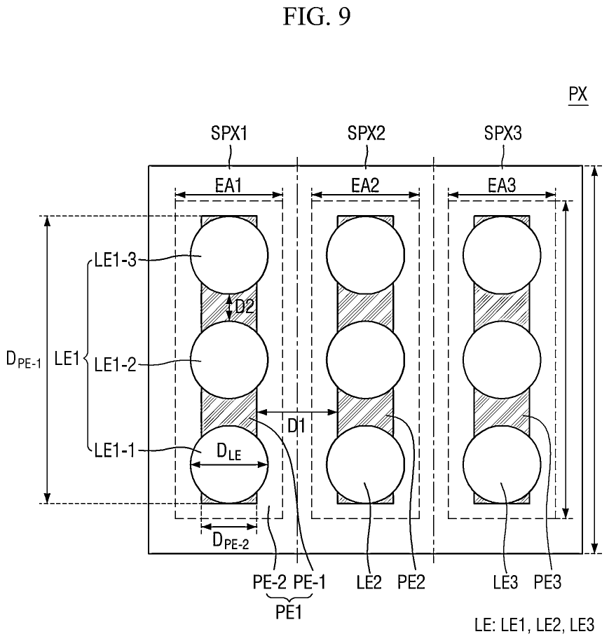

The connection electrode 150 may be disposed on the plurality of pixel electrodes PE1, PE2, and PE3. The connection electrode 150 may be in direct contact with the plurality of pixel electrodes PE1, PE2, and PE3. In an embodiment, the width of the connection electrode 150 is the same as that of the light emitting element LE as shown in FIG. 8. Hereinafter, the width of the light emitting element LE and the width of the connection electrode 150 may be used interchangeably. However, as shown in FIG. 7, when the width of the light emitting element LE increases from one end to the other end, the width of the light emitting element LE is the width of the first semiconductor layer SEM1. In an embodiment, the width of the light emitting element LE is greater than that of the corresponding pixel electrode (e.g., PE1). The width of the light emitting element LE and the corresponding width of the pixel electrode will be described below with reference to FIG. 9.

The connection electrode 150 may include a reflective layer 151 and a connection layer 153. The reflective layer 151 may serve to reflect light emitted from the active layer MQW of the light emitting element LE. The reflective layer 151 may be disposed adjacent to the active layer MQW of the light emitting element LE. The reflective layer 151 may include a metal material having conductivity and high light reflectivity. The reflective layer 151 may include, e.g., aluminum (Al) or silver (Ag), or an alloy thereof.

The connection layer 153 may serve to transmit an emission signal from the first pixel electrode PE1 to the light emitting element LE. The connection layer 153 may be an ohmic connection electrode. However, the present disclosure is not limited thereto since the connection layer 153 may be a Schottky connection electrode. The connection layer 153 may be disposed at the lowermost end of the light emitting element LE, and may be more distant from the active layer MQW than the reflective layer 151. The connection layer 153 may include at least one of gold (Au), copper (Cu), tin (Sn), silver (Ag), aluminum (Al), or titanium (Ti). For example, the connection layer 153 may contain a 9:1 alloy, a 8:2 alloy or a 7:3 alloy of gold and tin, or may contain an alloy (SAC305) of copper, silver, and tin.

Although FIGS. 7 and 8 illustrate the connection electrode 150 in which the light emitting element LE has a double-layer structure of one reflective layer 151 and the connection layer 153, the present disclosure is not limited thereto. In some cases, the light emitting element LE may include the connection electrode 150 in which a larger number of layers are stacked, or some layers may be omitted.

The first semiconductor layer SEM1 may be disposed on the connection electrode 150. The first semiconductor layer SEM1 may be a p-type semiconductor, and may include a semiconductor material having a chemical formula of AlxGayIn1-x-yN (0≤x≤1, 0≤y≤1, 0≤x+y≤1). For example, it may be any one or more of p-type doped AlGaInN, GaN, AlGaN, InGaN, AlN and InN. The first semiconductor layer SEM1 may be doped with a p-type dopant, and the p-type dopant may be Mg, Zn, Ca, Se, Ba, or the like. For example, the first semiconductor layer SEM1 may be p-GaN doped with p-type Mg. The thickness of the first SEM1 conductor layer SEM1 may be in a range of 30 nm to 200 nm, but is not limited thereto.

The active layer MQW may be disposed on the first semiconductor layer SEM1. The active layer MQW may emit light by coupling of electron-hole pairs according to an electrical signal applied through the first semiconductor layer SEM1 and the second semiconductor layer SEM2. The active layer MQW may emit first light having a central wavelength band of 450 nm to 495 nm, i.e., light of a blue wavelength band.

The active layer MQW may include a material having a single or multiple quantum well structure. When the active layer MQW contains a material having a multiple quantum well structure, the active layer MQW may have the structure in which a plurality of well layers and barrier layers are alternately laminated. The well layer may be formed of InGaN, and the barrier layer may be formed of GaN or AlGaN, but the present disclosure is not limited thereto. The thickness of the well layer may be approximately 1 to 4 nm, and the thickness of the barrier layer may be 3 nm to 10 nm.

Alternatively, the active layer MQW may have a structure in which semiconductor materials having large band gap energy and semiconductor materials having small band gap energy are alternately stacked, and may include other group III to V semiconductor materials according to the wavelength band of the emitted light. The light emitted by the active layer MQW is not limited to the first light, and in some cases, second light (light of the green wavelength band) or third light (light of the red wavelength band) may be emitted. In an embodiment, when the semiconductor materials included in the active layer MQW include indium, the color of emitted light may vary depending on the content of indium. For example, as the content of indium decreases, the wavelength band of the light emitted from the active layer may shift to a red wavelength band, and as the content of indium increases, the wavelength band of the light emitted from the active layer may shift to a blue wavelength band.

The second semiconductor layer SEM2 may be disposed on the active layer MQW. The second semiconductor layer SEM2 may be an n-type semiconductor. The second semiconductor layer SEM2 may include a semiconductor material having a chemical formula of AlxGayIn1-x-yN (0≤x≤1, 0≤y≤1, 0≤x+y≤1). For example, it may be any one or more of n-type doped AlGaInN, GaN, AlGaN, InGaN, AIN and InN. The second semiconductor layer SEM2 may be doped with an n-type dopant, and the n-type dopant may be Si, Ge, Sn, or the like. For example, the second semiconductor layer SEM2 may be n-GaN doped with n-type Si. The thickness of the second semiconductor layer SEM2 may be within a range of 2 μm to 4 μm, but the present disclosure is not limited thereto.

In an embodiment, an electron blocking layer is disposed between the first semiconductor layer SEM1 and the active layer MQW. The electron blocking layer may be disposed on the first semiconductor layer SEM1. The electron blocking layer may be a layer for suppressing or preventing too many electrons from flowing into the active layer MQW. For example, the electron blocking layer EBL may be p-AlGaN doped with p-type Mg. The thickness of the electron blocking layer may be within a range of 10 nm to 50 nm, but the present disclosure is not limited thereto. Further, the electron blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN or GaN. The thickness of the superlattice layer SLT may be about 50 nm to 200 nm. The superlattice layer may be omitted.

Further, the light emitting element LE may include a first side insulating layer INS1, a side reflective layer RFL1, and a second side insulating layer INS2 that sequentially surround the first semiconductor layer SEM1, the active layer MQW, and the second semiconductor layer SEM2.

The first side insulating layer INS1 may surround the side surfaces of the light emitting element LE, e.g., the outer circumferential surfaces thereof. The first side insulating layer INS1 may insulate the light emitting elements LE from other layers. The first side insulating layer INS1 may be directly disposed on the outer peripheral surface of the first semiconductor layer SEM1, the second semiconductor layer SEM2, and the active layer MQW to surround them. In an embodiment, the first side insulating layer INS1 surrounds the entire outer peripheral surface of the first semiconductor layer SEM1, the active layer MQW, and the second semiconductor layer SEM2.

The first side insulating layer INS1 may be disposed to surround the light emitting elements LE. The first side insulating layer INS1 may include an inorganic insulating material such as silicon oxide (SiOₓ), silicon nitride (SiNₓ), silicon oxynitride (SiOₓN_{y}), aluminum oxide (AlₓO_{y}), and aluminum nitride (AlN). The thickness of the first side insulating layer INS1 may be about 0.1 μm, but is not limited thereto.

The side reflective layer RFL1 may be disposed on the first side insulating layer INS1. The side reflective layer RFL1 may be disposed to surround the side surface of the light emitting element LE. For example, the first reflective layer RFL1 may surround the outer peripheral surface of the light emitting element LE, and may surround the side surfaces of the first semiconductor layer SEM1, the active layer MQW, and the second semiconductor layer SEM2 of the light emitting element LE.

The side reflective layer RFL1 may reflect light emitted from the light emitting element LE. For example, the side reflective layer RFL1 may reflect light emitted from the active layer MQW of the light emitting element LE and emitted to the side surface, upward (e.g., in the third direction DR3). That is, the side reflective layer RFL1 may increase light output efficiency of the light emitting element LE. To this end, the side reflective layer RFL1 may be disposed to surround at least the side surface of the active layer MQW of the light emitting element LE.

The side reflective layer RFL1 may include a metal material having a high reflectance. For example, the first reflective layer RFL1 may include aluminum or silver, or may also be an alloy thereof.

The second side insulating layer INS2 may be disposed on the side reflective layer RFL1 to surround the outside of the light emitting element LE. For example, the second side insulating layer INS2 is formed to surround the side surface and the top surface of the side reflective layer RFL1, but both ends of the light emitting element LE in the longitudinal direction may be at least partially exposed. In an embodiment, the second side insulating layer INS2 does not cover the first semiconductor layer SEM1 and the second semiconductor layer SEM2 of the light emitting element LE. One end of the second side insulating layer INS2 in contact with the common electrode CE may coincide with those of the first side insulating layer INS1 and the reflective layer RFL1.

The second side insulating layer INS2 may include the same material as the first side insulating layer INS1. The second side insulating layer INS2 may include an inorganic insulating material such as silicon oxide (SiOₓ), silicon nitride (SiNₓ), silicon oxynitride (SiOₓN_{y}), aluminum oxide (AlₓO_{y}), and aluminum nitride (AIN). The thickness of the second side insulating layer INS2 may be about 0.1 μm, but is not limited thereto.

A third planarization layer 135 may be disposed on the second planarization layer 130 where the pixel electrodes PE1, PE2, and PE3 are not disposed. The third planarization layer 135 may include an organic material to flatten stepped portions of the pixel electrodes PE1, PE2, and PE3. For example, the third planarization layer 135 may include acrylic resin, epoxy resin, phenolic resin, polyamide resin, polyimide resin, unsaturated polyester resin, polyphenylene resin, polyphenylenesulfide resin, benzocyclobutene (BCB), or the like.

Referring to FIG. 6, a second planarization layer PLL may be disposed on the third planarization layer 135 where the plurality of light emitting elements LE1, LE2, and LE3 are not disposed. The second planarization layer PLL may flatten a lower step so that the common electrode CE may be formed. The second planarization layer PLL may be formed of the same material as the third planarization layer 135, but is not limited thereto.

The common electrode CE may be disposed on the planarization layer PLL and the plurality of light emitting elements LE. Specifically, the common electrode CE may be disposed on one surface of the first substrate 110 on which the light emitting element LE is formed, and may be disposed entirely in the display area DPA and the non-display area NDA. The common electrode CE is disposed to overlap each of the emission areas EA1, EA2, and EA3 in the display area DPA, and may have a thin thickness to allow light to be emitted. For example, the thickness of the common electrode CE may be approximately 10 Å to 200 Å, but is not limited thereto.

The common electrode CE may be directly disposed on the top surface and the side surface of the plurality of light emitting elements LE. The common electrode CE may be in direct contact with the second semiconductor layer SEM2 of the side surface of the light emitting element LE. As illustrated in FIG. 6, the common electrode CE may be a common layer that covers the plurality of light emitting elements LE and is disposed by commonly connecting the plurality of light emitting elements LE. Since the conductive second semiconductor layer SEM2 has a patterned structure in each of the light emitting elements LE, a common voltage may be applied to each light emitting element LE via the common electrode CE.

Since the common electrode CE is entirely disposed on the first substrate 110 and a common voltage is applied, the common electrode CE may include a material having a low resistance. For example, the common electrode CE may include a material having a low resistance, such as aluminum (Al), silver (Ag), copper (Cu), or the like.

The above-described light emitting elements LE may receive a pixel voltage or an anode voltage from each of the pixel electrodes PE1, PE2, and PE3, and may receive a common voltage through the common electrode CE. The light emitting elements LE may emit light with a predetermined luminance according to a voltage difference between the pixel voltage and the common voltage.

Meanwhile, the wavelength converter 200 may be disposed on the light emitting element unit LEP. The wavelength converter 200 may include a partition wall PW, a wavelength conversion layer QDL, the color filters CF1, CF2, and CF3, the light blocking member BK, and a passivation layer PTL.

The partition wall PW may be disposed on the common electrode CE of the display area DPA, and may partition the plurality of emission areas EA1, EA2, and EA2. The partition wall PW may be disposed to extend in the first direction DR1 and the second direction DR2, and may be formed in a grid pattern in the entire display area DPA. Further, the partition wall PW may not overlap the plurality of emission areas EA1, EA2, and EA3, and may overlap the non-emission area NEA.

The partition wall PW may include a plurality of openings OP1, OP2, and OP3 exposing the lower common electrode CE. The plurality of openings OP1, OP2, and OP3 may include a first opening OP1 overlapping the first emission area EA1, a second opening OP2 overlapping the second emission area EA2, and a third opening OP3 overlapping the third emission area EA3. Here, the plurality of openings OP1, OP2, and OP3 may correspond to the plurality of emission areas EA1, EA2, and EA3. That is, the first opening OP1 may correspond to the first emission area EA1, the second opening OP2 may correspond to the second emission area EA2, and the third opening OP3 may correspond to the third emission area EA3.

The partition wall PW may serve to provide a space for forming the wavelength conversion layer QDL. To this end, the partition wall PW may have a predetermined thickness. For example, the thickness of the partition wall PW may be in the range of 1 μm to 10 μm. The partition wall PW may contain an organic insulating material to have a predetermined thickness. The organic insulating material may contain, for example, epoxy resin, acrylic resin, cardo resin or imide resin.

The wavelength conversion layer QDL may be disposed on each of the plurality of openings OP1, OP2, and OP3. The wavelength conversion layer QDL may emit light by converting or shifting the peak wavelength of incident light to another specific peak wavelength. The wavelength conversion layer QDL may convert a portion of the first blue light emitted from the light emitting element LE into the fourth yellow light. In the wavelength conversion layer QDL, the first light and the fourth light may be mixed to emit the fifth white light. The fifth light may be converted into the first light through a first color filter CF1, converted into the second light through a second color filter CF2, and converted into the third light through a third color filter CF3.

The wavelength conversion layer QDL may be disposed in each of the plurality of openings OP1, OP2, and OP3, and may be disposed to be spaced apart from each other. For example, the wavelength conversion layer QDL may include portions that are spaced apart from each other. That is, the wavelength conversion layer QDL may be formed of an island pattern in a shape of dots spaced apart from each other. For example, the wavelength conversion layer QDL may be disposed in each of the first opening OP1, the second opening OP2, and the third opening OP3 in a one-to-one correspondence. Further, the wavelength conversion layer QDL may be disposed to overlap each of the first emission area EA1, the second emission area EA2, and the third emission area EA3. In an embodiment, each of the wavelength conversion layers QDL completely overlap the first emission area EA1, the second emission area EA2, and the third emission area EA3.

The wavelength conversion layer QDL may include a first base resin BRS1 and a first wavelength conversion particle WCP1. The first base resin BRS1 may include a light-transmissive organic material. For example, the first base resin BRS1 may contain epoxy resin, acrylic resin, cardo resin, or imide resin.

The first wavelength conversion particle WCP1 may convert the first light incident from the light emitting element LE into a fourth light. For example, the first wavelength conversion particle WCP1 may convert light of a blue wavelength band into light of a yellow wavelength band. The first wavelength conversion particle WCP1 may be a quantum dot (QD), a quantum rod, a fluorescent material, or a phosphorescent material. For example, a quantum dot may be a particulate material that emits light of a specific color when an electron transitions from a conduction band to a valence band.

The quantum dot may be a semiconductor nanocrystal material. The quantum dot may have a specific band gap according to its composition and size. Thus, the quantum dot may absorb light and then emit light having an intrinsic wavelength. Examples of semiconductor nanocrystal of quantum dots may include group IV nanocrystal, group II-VI compound nanocrystal, group III-V compound nanocrystal, group IV-VI nanocrystal, a combination thereof, or the like.

The group II-VI compound may be selected from the group consisting of binary compounds, ternary compounds, and quaternary compounds. The binary compounds may be selected from the group consisting of CdSe, CdTe, ZnS, ZnSe, ZnTe, ZnO, HgS, HgSe, HgTe, MgSe, MgS and mixtures thereof. The ternary compounds may be selected from the group consisting of InZnP, AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSc, HgZnTc, MgZnSc, MgZnS and mixtures thereof. The quaternary compounds may be selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compound may be selected from the group consisting of binary compounds, ternary compounds, and quaternary compounds. The binary compounds may be selected from the group consisting of GaN, GaP, GaAs, GaSb, AlN, AlP, AlAs, AlSb, InN, InP, InAs, InSb and mixtures thereof. The ternary compounds may be selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and mixtures thereof. The quaternary compounds may be selected from the group consisting of GaAlNAs, GaAlNSb, GaAlPAs, GaAlPSb, GaInNP, GaInNAs, GaInNSb, GalnPAs, GaInPSb, InAlNP, InAlNAs, InAlNSb, InAlPAs, InAlPSb and mixtures thereof.

The group IV-VI compound may be selected from the group consisting of binary compounds, ternary compounds, and quaternary compounds. The binary compounds are selected from the group consisting of SnS, SnSe, SnTe, PbS, PbSe, PbTe and mixtures thereof, the ternary compounds are selected from the group consisting of SnSeS, SnSeTe, SnSTe, PbSeS, PbSeTe, PbSTe, SnPbS, SnPbSc, SnPbTe and mixtures thereof. The quaternary compounds are selected from the group consisting of SnPbSSe, SnPbSeTe, SnPbSTe and mixtures thereof. The group IV element may be selected from the group consisting of Si, Ge and mixtures thereof. The group IV compound may be a binary compound selected from the group consisting of SiC, SiGe and mixtures thereof.

The binary compound, the tertiary compound or the quaternary compound may exist in particles at a uniform concentration, or may exist in the same particle divided into states where concentration distributions are partially different. Further, the particles may have a core/shell structure in which one quantum dot surrounds another quantum dot. An interface between the core and the shell may have a concentration gradient in which the concentration of elements present in the shell decreases toward the center.

In an embodiment, the quantum dot has a core-shell structure including a core including the nanocrystal described above and a shell surrounding the core. The shell of the quantum dot may serve as a protective layer for maintaining semiconductor characteristics by preventing chemical denaturation of the core and/or as a charging layer for giving electrophoretic characteristics to the quantum dot. The shell may be a single layer or a multilayer. Examples of the shell of the quantum dot may include a metal or non-metal oxide, a semiconductor compound, and a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a tertiary compound such as MgAl₂O₄, CoFc₂O₄, NiFe₂O₄and CoMn₂O₄, but the present disclosure is not limited thereto.

In addition, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, but is not limited thereto.

The wavelength conversion layer QDL may further include a scatterer for scattering the light of the light emitting element LE in random directions. The scatterer may have a refractive index different from that of the first base resin BRS1 and form an optical interface with the first base resin BRS1. For example, the scatterer may be light scattering particles. The scatterer may be a material capable of scattering at least a portion of the transmitted light, but may be, for example, metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), and tin oxide (SnO₂). Examples of a material of the organic particles may include acrylic resin and urethane resin, and the like. The scatterer may scatter light in random directions regardless of the incidence direction of the incident light without substantially converting the wavelength of the light.

In an embodiment, as the thickness of the wavelength conversion layer QDL increases in the third direction DR3, the content of the first wavelength conversion particles WCP1 included in the wavelength conversion layer QDL increases, so that the light conversion efficiency of the wavelength conversion layer QDL increases. Accordingly, the thickness of the wavelength conversion layer QDL may be set in consideration of the light conversion efficiency of the wavelength conversion layer QDL.

In the above-described wavelength converter 200, a part of the first light emitted from the light emitting element LE may be converted into fourth light in the wavelength conversion layer QDL. The wavelength conversion layer QDL may emit the fifth white light that is the color mixture of the first light and the fourth light. For the fifth light emitted from the wavelength conversion layer QDL, the first color filter CF1 to be described below may transmit only the first light, the second color filter CF2 may transmit only the second light, and the third color filter CF3 may transmit only the third light. Accordingly, light emitted from the wavelength converter 200 may be blue light, red light, and green light of the first light, the second light, and the third light, respectively, thereby implementing full color.

The plurality of color filters CF1, CF2, and CF3 may be disposed on the partition wall PW and the wavelength conversion layer QDL. The plurality of color filters CF1, CF2, and CF3 may be disposed to overlap the plurality of openings OP1, OP2, OP3 and the wavelength conversion layer QDL. The plurality of color filters CF1, CF2, and CF3 may include the first color filter CF1, the second color filter CF2, and the third color filter CF3.

The first color filter CF1 may be disposed to overlap the first emission area EA1, and a part thereof may overlap the non-emission area NEA. In addition, the first color filter CF1 may be disposed on the first opening OP1 of the partition wall PW to overlap the first opening OP1, and may partially overlap the light blocking member BK. The first color filter CF1 may transmit the first light emitted from the light emitting element LE and absorb or block the second light and the third light. For example, the first color filter CF1 may transmit light of a blue wavelength band and absorb or block light of other wavelength bands such as green and red.

The second color filter CF2 may be disposed to overlap the second emission area EA2, and a part thereof may overlap the non-emission area NEA. In addition, the second color filter CF2 may be disposed on the second opening OP2 of the partition wall PW to overlap the second opening OP2, and may partially overlap the light blocking member BK. The second color filter CF2 may transmit the second light and absorb or block the first light and the third light. For example, the second color filter CF2 may transmit light of a green wavelength band and absorb or block light of other wavelength bands such as blue and red.

The third color filter CF3 may be disposed to overlap the third emission area EA3, and a part thereof may overlap the non-emission area NEA. In addition, the third color filter CF3 may be disposed on the third opening OP3 of the partition wall PW to overlap the third opening OP3, and may partially overlap the light blocking member BK. The third color filter CF3 may transmit the third light and absorb or block the first light and the second light. For example, the third color filter CF3 may transmit light of a red wavelength band and absorb or block light of other wavelength bands such as blue and green.

The light blocking member BK may be disposed on the partition wall PW. The light blocking member BK may overlap the non-emission area NEA to block transmission of light. The light blocking member BK may be disposed approximately in a lattice shape in a plan view similarly to the partition wall PW. In an embodiment, the light blocking member BK is disposed to overlap the partition wall PW, and does not overlap the emission areas EA1, EA2, and EA3. In an embodiment, the light blocking member BK does not overlap a pixel electrode (e.g., PE1, PE2, PE3, etc.).

In an embodiment, the light blocking member BK contains an organic light blocking material, and may be formed by a process of coating and exposing the organic light blocking material. The light blocking member BK may include a dye or a pigment having a light blocking property, and may be a black matrix. At least a part of the light blocking member BK may overlap the adjacent color filters CF1, CF2, and CF3, and the color filters CF1, CF2, and CF3 may be disposed on at least a part of the light blocking member BK.

External light incident from the outside of the display device 10 may cause color reproducibility of the wavelength converter 200 to be distorted. When the light blocking member BK is disposed on the wavelength converter 200 according to the present embodiment, at least a part of external light is absorbed by the light blocking member BK. Accordingly, color distortion caused by the reflection of the external light may be reduced. In addition, the light blocking member BK may prevent light interference between adjacent emission areas, which causes color mixture, thereby further increasing color reproducibility.

The passivation layer PTL may be disposed on the plurality of color filters CF1, CF2, and CF3 and the light blocking member BK. The first passivation layer PTL may be disposed on the uppermost portion of the display device 10 to protect the lower plurality of color filters CF1, CF2, and CF3 and the light blocking member BK. One surface, for example, a bottom surface of the passivation layer PTL may be in contact with the top surface of each of the plurality of color filters CF1, CF2, and CF3 and the light blocking member BK.

The passivation layer PTL may include an inorganic insulating material to protect the plurality of color filters CF1, CF2, and CF3 and the light blocking member BK. For example, the first passivation layer PTL may include silicon oxide (SiOₓ), silicon nitride (SiNₓ), silicon oxynitride (SiOₓN_{y}), aluminum oxide (AlₓO_{y}), or aluminum nitride (AlN), but is not limited thereto. The first passivation layer PTF1 may have a predetermined thickness, for example, in a range of 0.01 μm to 1 μm. However, the present disclosure is not limited thereto.

Referring to FIG. 7 and FIG. 8, the light emitting element LE may have different shapes. For example, in FIG. 7, sides of the light emitting element LE are sloped at an angle and become narrower towards its bottom surface; and in FIG. 8, the sides of the light emitting element LE are not sloped or are straight.

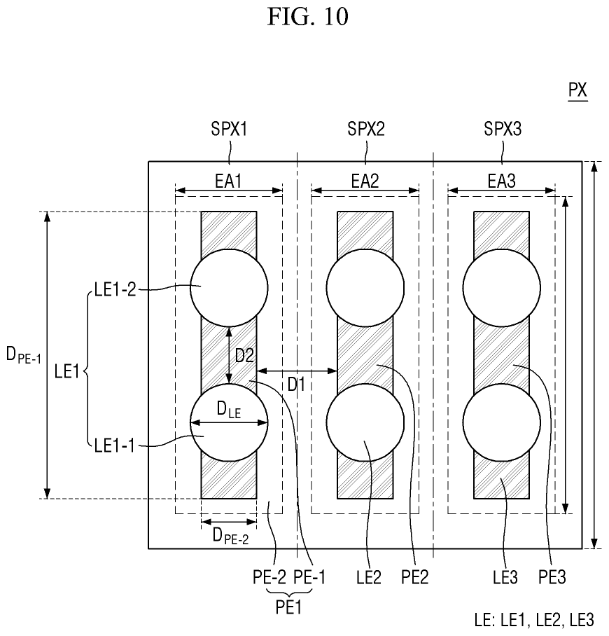

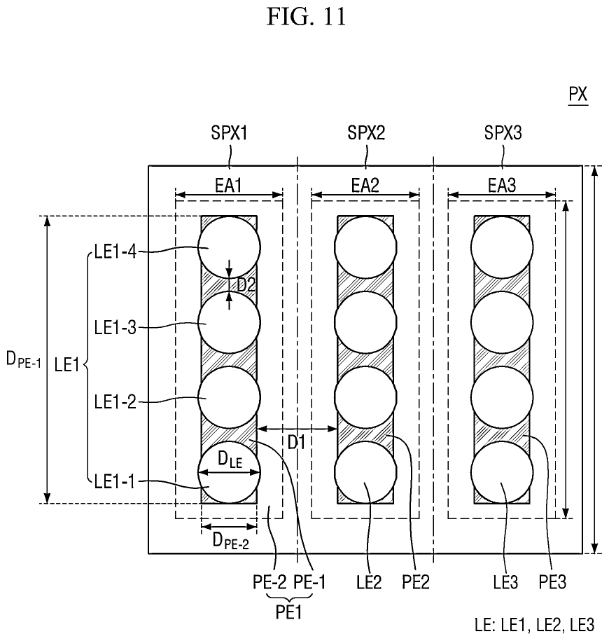

FIG. 9 is a plan view of a pixel electrode and a light emitting element according to an embodiment. FIG. 10 is a plan view of a pixel electrode and a light emitting element according to an embodiment. FIG. 11 is a plan view of a pixel electrode and a light emitting element according to an embodiment.

Referring to FIG. 9, the display area DPA of the display device 10 (see FIG. 1) may include the plurality of pixels PX. The pixel PX may be defined as a minimum light emitting unit capable of displaying white light.

Each of the pixels PX may include first to third sub-pixels SPX1, SPX2, and SPX3 that emit light. Each of the sub-pixels SPX1, SPX2, and SPX3 may include a plurality of light emitting elements LE. In an embodiment of the present disclosure, each of the sub-pixels SPX includes three light emitting elements LE, but the present disclosure is not limited thereto. Each of the sub-pixels SPX may include two light emitting elements LE, or four light emitting elements LE, as illustrated in FIGS. 10 and 11. Further, each of the light emitting elements LE is illustrated as having a circular shape in a plan view, but embodiments of the present disclosure are not limited thereto. Each of the light emitting elements LE may have a polygonal shape such as a triangular shape, a quadrilateral shape, a pentagonal shape, a hexagonal shape, and an octagonal shape, an elliptical shape, or an atypical shape.

The first pixel electrode PE1, the second pixel electrode PE2, and the third pixel electrode PE3 may have a rectangular shape with a long side PE-1 located in a vertical direction. However, they are not limited thereto, and may have a rectangular shape with a short side PE-2 located in the vertical direction. The length D_{PE-1} of the long side PE-1 of the pixel electrode PE may be about 45 μm to 55 μm. The length D_{PE-2} of the short side PE-2 may be about 6 μm to 8 μm. For example, the length of the long side PE-1 of the pixel electrode PE may be 50 μm, and the length of the short side PE-2 thereof may be 7 μm.

The first pixel electrode PE1, the second pixel electrode PE2, and the third pixel electrode PE3 may have a rectangular shape with the long side PE-1 located in the vertical direction. However, they are not limited thereto, and may have a rectangular shape with the short side PE-2 located in the vertical direction.

The first pixel electrode PE1, the second pixel electrode PE2, and the third pixel electrode PE3 may be arranged to be aligned on an arbitrary line extending in one direction. For example, the pixel electrodes may be arranged in a matrix, and may be arranged to be spaced apart from each other at the same first interval D1. The first interval D1 is referred to as a separation distance. The separation distance may be about 18 μm to 19 μm. For example, the first interval D1 may be 19 μm.

In an embodiment, a ratio of the length of the short side PE-2 of the pixel electrodes PE1, PE2, and PE3 to the separation distance D1 among the pixel electrodes PE1, PE2, and PE3 is about 1:1.7 to 1:1.8.

A plurality of light emitting elements LE may be disposed on one pixel electrode PE1, PE2, PE3. For example, three light emitting elements LE may be disposed on the first pixel electrode PE1. The plurality of light emitting elements LE may be arranged at the same second interval D2. For example, the second interval D2 may be 10 μm to 20 μm. For example, the second interval D2 may be 15 μm. For example, the light emitting elements LE may be spaced apart from each other at the same second interval D2 in a vertical direction.

A width or diameter D_{LE} of the light emitting element LE may be about 8 μm to 16 μm. In an embodiment, the width or diameter D_{LE} of the light emitting element LE is longer than the length of the short side PE-2 of the pixel electrodes PE1, PE2, and PE3. For example, the length of the short side PE-2 may be 7 μm, and the separation distance D1 among the pixel electrodes PE1, PE2, and PE3 may be 19 μm. The width or diameter D_{LE} of the light emitting element LE may be longer than the length of the short side PE-2 of the pixel electrodes PE1, PE2, and PE3, and may be smaller than the separation distance D1 among the pixel electrodes PE1, PE2, and PE3. In this way, the light emitting element LE does not interfere with a neighboring pixel electrode. Thus, it is possible to control light emission of the respective sub-pixels SPX.

In an embodiment, the ratio of the length of the short side PE-2 of the pixel electrodes PE1, PE2, and PE3 to the width or diameter D_{LE} of the light emitting element LE is about 1:1.5 to 1:2.3. By disposing the pixel electrodes PE1, PE2, and PE3, the short side PE-2 of which has a length smaller than the width or diameter D_{LE} of the light emitting element LE, it is possible to prevent a phenomenon in which the light emitting element LE is biased to the edge of the pixel electrode PE1 in the pixel electrode PE1 and collapses. When the width or diameter D_{LE} of the light emitting element LE is sufficiently larger than the length of the short side PE-2 of the pixel electrodes PE1, PE2, and PE3, the light emitting element LE does not collapse even if it is disposed to be biased to the edge of the pixel electrode PE1 in the pixel electrode PE1. However, when the width or diameter D_{LE} of the light emitting element LE is greater than about 2.3 times the length of the short side PE-2 of the pixel electrodes PE1, the supporting pixel electrode PE1 becomes very narrow, and thus alignment of the light emitting element LE may become more difficult. When the width or diameter D_{LE} of the light emitting element LE is about 1.5 times to 2.3 times the length of the short side PE-2 of the pixel electrodes PE1, PE2, and PE3, the light emitting element LE may be prevented from collapsing when it is disposed to be biased to the edge of the pixel electrode PE1.

In an embodiment, the length of the short side PE-2 of the pixel electrodes PE1, PE2, and PE3 is sufficiently small with respect to the width or diameter D_{LE} of the light emitting element LE so that the light absorption by the pixel electrodes PE1, PE2, and PE3 may be reduced. Thus, the light output efficiency may be increased. Further, since the sizes of the pixel electrodes PE1, PE2, and PE3 are reduced, moisture permeation reliability or heat resistance reliability due to the external characteristics may be decreased.

Referring to FIGS. 9 to 11, two to four light emitting elements LE may be disposed on one pixel electrode PE1, PE2, PE3. When less than two light emitting elements LE are disposed, that is, when one light emitting element LE is disposed on one pixel electrode PE1, PE2, PE3, the light emission efficiency may be decreased. Further, when more than four light emitting elements LE are disposed on one pixel electrode PE1, PE2, PE3, the light emission efficiency may be decreased by interference between the light emitting elements LE disposed in one pixel electrode.

Referring to FIG. 10, it is different from FIG. 9 in that two light emitting elements LE are disposed on each of the pixel electrodes PE. Referring to FIG. 11, it is different from FIG. 9 in that four light emitting elements LE are disposed on each of the pixel electrodes PE.

Referring to FIGS. 10 and 11, the lengths of the long and short sides of the pixel electrode PE may be the same as described in FIG. 9. For example, the length of the long side PE-1 may be about 45 μm to 55 μm. The length of the short side PE-2 may be about 6 μm to 8 μm.

Further, the first pixel electrode PE1, the second pixel electrode PE2, and the third pixel electrode PE3 may be arranged to be aligned on an arbitrary line extending in one direction. For example, they may be arranged in a matrix and may be arranged to be spaced apart from each other at the same first interval D1. The first interval D1 is referred to as a separation distance. One separation distance may be about 18 μm to 19 μm. For example, the first interval D1 may be 19 μm.

In an embodiment, the ratio of the length of the short side PE-2 of the pixel electrodes PE1, PE2, and PE3 to the separation distance among the pixel electrodes PE1, PE2, and PE3 is about 1:1.7 to 1:1.8.

The width or diameter D_{LE} of the light emitting element LE may be about 8 μm to 16 μm. As the number of pixel electrodes PE in one pixel is reduced, the size of the light emitting element LE may increase, but the present disclosure is not limited thereto.

Referring to FIG. 9, the light emitting element LE1 may be implemented by light emitting elements LE1-1, LE1-2, and LE1-3.

Referring to FIG. 10, when one pixel electrode PE1, PE2, PE3 includes two pixel electrodes, the width or diameter D_{LE} of the light emitting element LE may be about 15 μm. The plurality of light emitting elements LE may be arranged at the same second interval D2. For example, the second interval D2 may be 15 μm to 20 μm. For example, the second interval D2 may be 20 μm. The light emitting element LE1 of FIG. 10 may be implemented by light emitting elements LE1-1 and LE1-2.

Referring to FIG. 11, when one pixel electrode PE1, PE2, PE3 includes four pixel electrodes, the width or diameter D_{LE} of the light emitting element LE may be about 15 μm. The plurality of light emitting elements LE may be arranged at the same second interval D2. For example, the second interval D2 may be 10 μm to 15 μm. For example, the second interval D2 may be 10 μm. The light emitting element LE1 of FIG. 11 may be implemented by light emitting elements LE1-1, LE1-2, LE1-3, and LE1-4.

Hereinafter, a manufacturing process of the display device 10 according to an embodiment will be described with reference to other drawings.

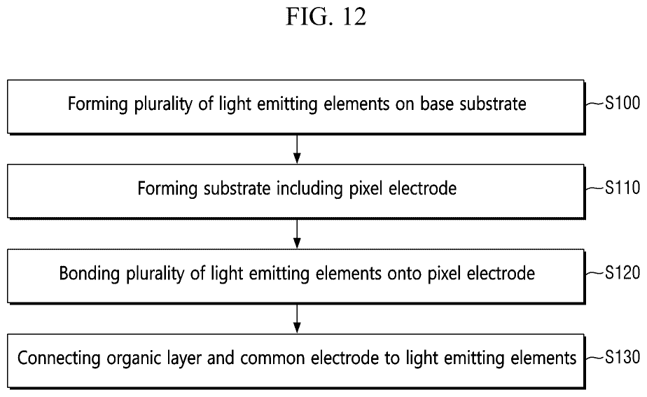

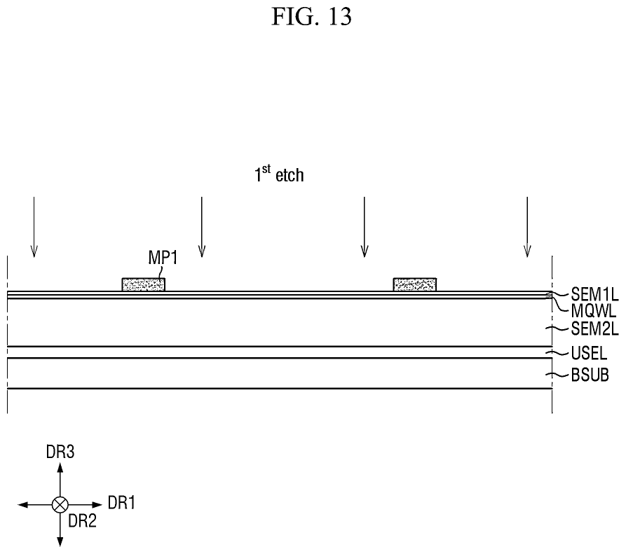

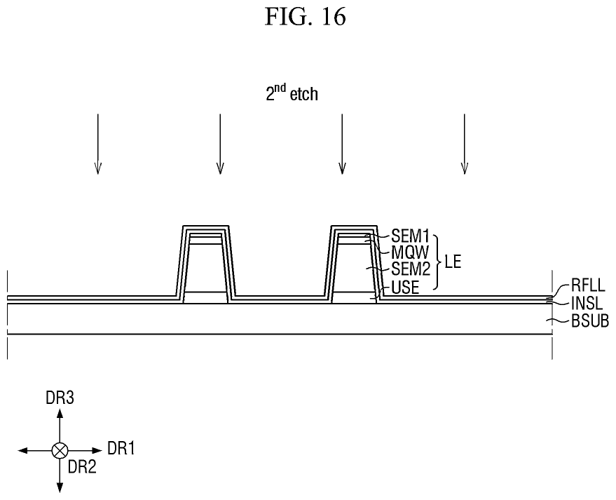

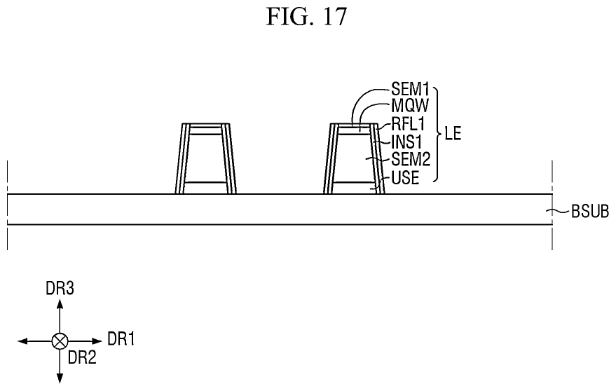

FIG. 12 is a flowchart illustrating a method of manufacturing a display device according to an embodiment. FIGS. 13 to 25 are views illustrating a method of manufacturing a display device according to an embodiment.

FIGS. 13 to 25 are cross-sectional views illustrating structures corresponding to the sequence of formation of the respective layers of the display device 10. FIGS. 13 to 25 mainly illustrate the manufacturing process of the light emitting element unit LEP of the display device 10, and these may generally correspond to the cross-sectional view of FIG. 6. Further, hereinafter, the first emission area EA1 and the second emission area EA2 of the display device 10 will be mainly described.

Referring to FIG. 12, a method of manufacturing the display device 10 according to an embodiment includes a step S100 of forming a plurality of light emitting elements on a base substrate, a step S110 of forming a substrate including a pixel electrode, a step S120 of bonding the plurality of light emitting elements onto the pixel electrode, and a step S130 of connecting an organic layer and a common electrode to the light emitting elements.

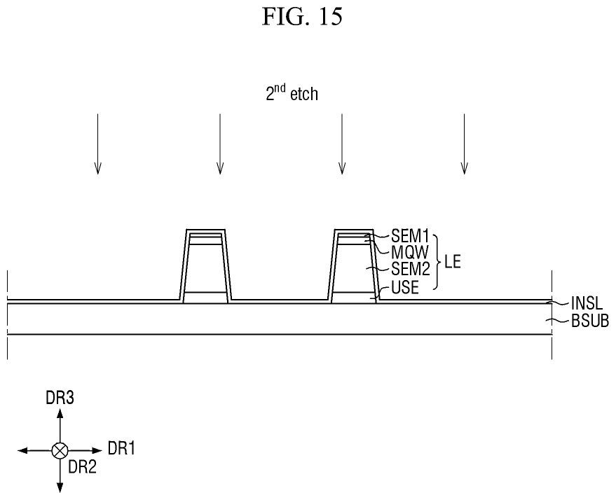

First, referring to FIGS. 13 and 15, the plurality of light emitting elements LE are formed on a base substrate BSUB.

Specifically, the base substrate BSUB is prepared. The base substrate BSUB may be a sapphire substrate (Al₂O₃) or a silicon wafer containing silicon. While a case in which the base substrate BSUB is a sapphire substrate will be described as an example, embodiments of the present disclosure are not limited thereto.

A plurality of semiconductor material layers USEL, SEM2L, MQWL, and SEM1L are formed on the base substrate BSUB. The plurality of semiconductor material layers grown by an epitaxial method may be formed by growing seed crystals. Here, the semiconductor material layer may be formed using one of electron beam deposition, physical vapor deposition (PVD), chemical vapor deposition (CVD), plasma laser deposition (PLD), dual-type thermal evaporation, sputtering, and metal organic chemical vapor deposition (MOCVD), preferably, using the metal organic chemical vapor deposition (MOCVD). However, the present disclosure is not limited thereto.

Typically, a precursor material for forming the plurality of semiconductor material layers may be selected to form a target material in a typically selectable range without any limitation. For example, the precursor material may be a metal precursor including an alkyl group such as a methyl group or an cthyl group. Examples of the precursor material may include, but are not limited to, trimethylgallium Ga(CH₃)₃, trimethylaluminum Al(CH₃)₃, and triethyl phosphate (C₂H₅)₃PO₄.

Specifically, a third semiconductor material layer USEL is formed on the base substrate BSUB. Although the drawings illustrate that the third semiconductor material layer USEL is stacked in one layer, the present disclosure is not limited thereto, and a plurality of layers may also be formed. The third semiconductor material layer USEL may be disposed to reduce a lattice constant difference between the second semiconductor material layer SEM2L and the base substrate BSUB. For example, the third semiconductor material layer USEL may include an undoped semiconductor, and may be a material that is not n-type or p-type doped. In an embodiment, the third semiconductor material layer USEL may be, but is not limited to, at least one of undoped InAlGaN, GaN, AlGaN, InGaN, AlN, or InN.

The second semiconductor material layer SEM2L, the active material layer MQWL, and the first semiconductor material layer SEM1L are sequentially formed on the third semiconductor material layer USEL by using the above-described method.

Next, the plurality of semiconductor material layers USEL, SEM2L, MQWL, and SEM1L are etched to form the plurality of light emitting elements LE.

Specifically, a plurality of first mask patterns MP1 are formed on the first semiconductor material layer SEM1L. The first mask pattern MP1 may be a hard mask including an inorganic material or a photoresist mask including an organic material. The first mask pattern MP1 prevents the plurality of semiconductor material layers USEL, SEM2L, MQWL, and SEM1L disposed therebelow from being etched. Then, the plurality of light emitting elements LE are formed by partially etching (1^{st} etch) the plurality of semiconductor material layers using the plurality of first mask patterns MP1 as a mask.

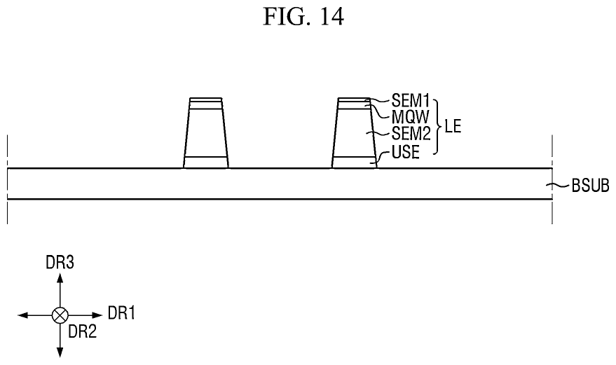

As illustrated in FIG. 14, the plurality of semiconductor material layers USEL, SEM2L, MQWL, and SEM1L that do not overlap the first mask pattern MP1 are etched and removed on the base substrate BSUB, and a portion that is not etched by overlapping with the first mask pattern MP1 may be formed to be the plurality of light emitting elements LE.

For example, the process of etching the semiconductor material layers may be performed by a dry etching method, a wet etching method, a reactive ion etching (RIE) method, a deep reactive ion etching (DRIE) method, an inductively coupled plasma reactive ion etching (ICP-RIE) method, or the like. The dry etching method may be suitable for vertical etching because anisotropic etching can be performed. In the case of using the aforementioned etching technique, it may be possible to use Cl₂ or O₂ as an etchant. However, the present disclosure is not limited thereto.

The plurality of semiconductor material layers USEL, SEM2L, MQWL, and SEM1L overlapping the first mask pattern MP1 are not etched and are formed as the plurality of light emitting elements LE. Accordingly, the plurality of light emitting elements LE is formed by including a third semiconductor layer USE, the second semiconductor layer SEM2, the active layer MQW, and the first semiconductor layer SEM1.

Next, referring to FIGS. 15 to 17, a first insulating layer and a reflective layer are formed on a side surface of the light emitting element LE.

Specifically, the insulating material layer INSL is formed on the outer surfaces of the plurality of light emitting elements LE. The insulating material layer INSL may be formed on the entire surface of the base substrate BSUB, and is formed not only on the light emitting element LE, but also on the top surface of the base substrate BSUB exposed by the light emitting element LE.

Then, a reflective material layer RFLL is formed on the first insulating layer INS. The reflective material layer RFLL is formed on the entire surface of the base substrate BSUB, so that it may be formed not only on the light emitting element LE, but also on the top surface of the base substrate BSUB exposed by the light emitting element LE, on the insulating material layer INSL.

Next, second etching (2^{nd} etch) is performed to partially remove the insulating material layer INSL and the reflective material layer RFLL, thereby forming the first insulating layer INS1 and a reflective layer RFL1 that expose the top surface of the light emitting element LE.

Specifically, the second etching (2^{nd} etch) may be performed to partially remove the insulating material layer INSL and the reflective material layer RFLL, so that the insulating material layer INSL and the reflective material layer RFLL surround the side surface of the light emitting element LE while exposing the top surface of the light emitting element LE. Specifically, in this process, the insulating material layer INSL and the reflective material layer RFLL may be partially removed to expose the top surface of the first semiconductor layer SEM1 of the light emitting element LE. The process of partially removing the insulating material layer INSL and the reflective material layer RFLL may be performed by a process such as etchback after dry etching that is anisotropic etching, but the present disclosure is not limited thereto. Accordingly, the first insulating layer INS1 and the reflective layer RFL1 surrounding the light emitting element LE may be formed.

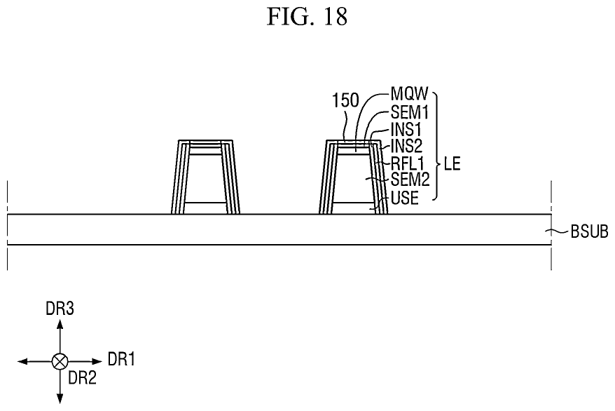

Next, referring to FIG. 18, the second insulating layer INS2 and the connection electrode 150 of the light emitting element LE are formed.

Specifically, the second insulating layer INS2 may be formed in the same manner as the manufacturing process of the first insulating layer INS1 described above. For example, the insulating material layer INSL is formed on the base substrate BSUB on which the light emitting element LE is formed, and the second insulating layer INS2 is formed on the outer surface of the light emitting element LE by performing the second etching (2^{nd} etch) that partially removes the insulating material layer INSL. However, the second insulating layer INS2 may be formed not only on the side surface of the light emitting element LE but also on a part of the top surface thereof. An opening is defined on the top surface of the light emitting element LE by the second insulating layer INS2.

The connection electrode 150 is formed on the top surface of the light emitting element LE defined by the second insulating layer INS2. The connection electrode 150 may be formed in the opening by laminating an electrode material layer on the base substrate BSUB, and then etching it through an etching process. The connection electrode 150 is formed on the first semiconductor layer SEM1 through the opening.

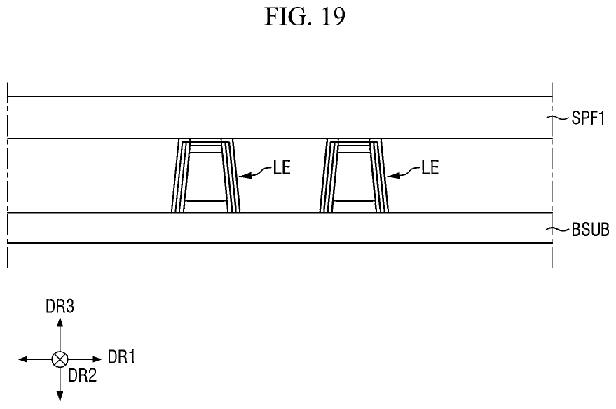

Referring to FIG. 19, a first support film SPF1 is attached on the plurality of light emitting elements LE of the base substrate BSUB manufactured in FIG. 18.

Specifically, the first support film SPF1 is attached onto the plurality of light emitting elements LE formed on the base substrate BSUB. The first support film SPF1 may be aligned on the plurality of light emitting elements LE, and may be attached to each connection electrode 150 of the plurality of light emitting elements LE. The plurality of light emitting elements LE may be disposed in large numbers, and thus may be attached to the first support film SPF1 without being detached.

The first support film SPF1 may be constituted with a support layer and an adhesive layer disposed on the support layer. The support layer may be made of a material that is transparent and has mechanical stability to allow light to pass therethrough. For example, the support layer may include a transparent polymer such as polyester, polyacrylic, polyepoxy, polyethylene, polystyrene, polyethylene terephthalate, or the like. The adhesive layer may include an adhesive material for the adhesion of the light emitting element LE. For example, the adhesive material may include urethane acrylates, epoxy acrylates, polyester acrylates, or the like. The adhesive material may be a material whose adhesive strength changes as ultraviolet (UV) or heat is applied, and thus the adhesive layer may be easily separated from the light emitting element LE.

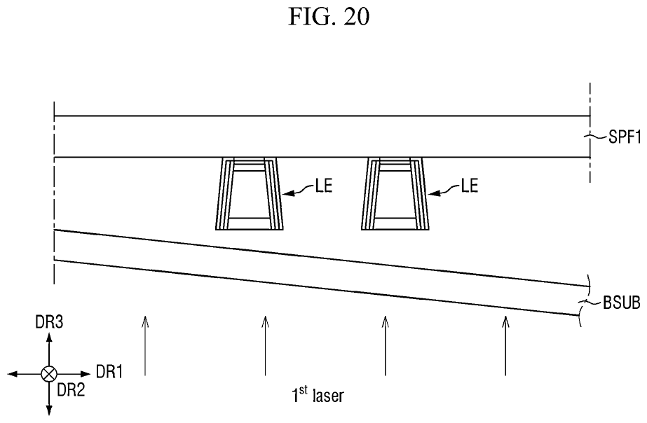

Subsequently, referring to FIG. 20, the light emitting elements LE are separated from the base substrate BSUB by irradiating the base substrate BSUB with a laser (1^{st} laser). The base substrate BSUB is separated from each of the third semiconductor layers USE of the plurality of light emitting elements LE.

The process of separating the base substrate BSUB may be a laser lift off (LLO) process. In the laser lift off process using a laser, a KrF excimer laser (248 nm wavelength) may be used as a source. The energy density of the excimer laser may be irradiated in the range of about 550 mJ/cm² to 950 mJ/cm², and the incident area may be in the range of 50×50 μm² to 1×1 cm², but the present disclosure is not limited thereto. By irradiating the laser to the base substrate BSUB, the base substrate BSUB may be separated from the light emitting element LE.

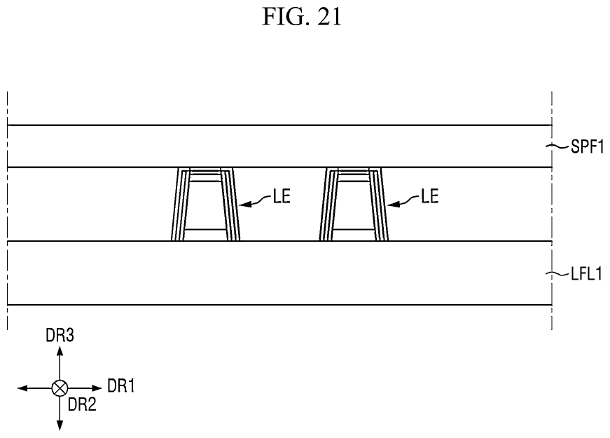

Next, referring to FIG. 21, the first transfer film LFL1 is attached to the plurality of light emitting elements LE separated from the base substrate BSUB.

Specifically, the first transfer film LFL1 is attached on each of the third semiconductor layers USE of the plurality of light emitting elements LE. The first transfer film LFL1 may be aligned on the plurality of light emitting elements LE and may be attached to each of the third semiconductor layers USE of the plurality of light emitting elements LE.

The first transfer film LFL1 may include a stretchable material. The stretchable material may include, e.g., polyolefine, polyvinyl chloride (PVC), elastomeric silicone, elastomeric polyurethane, elastomeric polyisoprene, or the like. Like the above-described first support film SPF1, the first transfer film LFL1 may also include a support layer and an adhesive layer to adhere and support the plurality of light emitting elements LE. The plurality of light emitting elements LE are disposed to be spaced apart at the predetermined first interval D1.

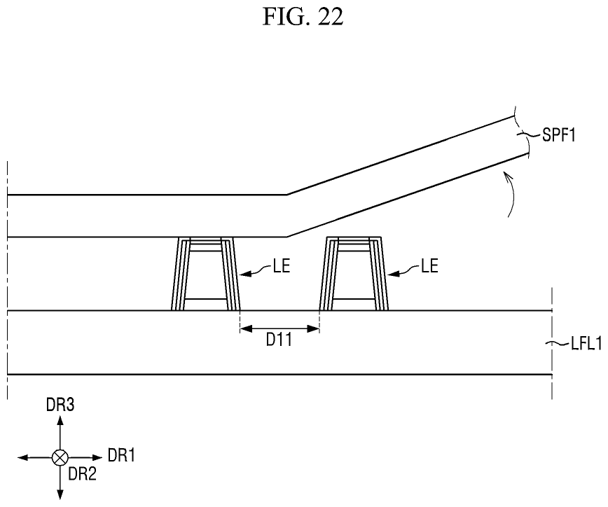

Then, referring to FIG. 22, the first support film SPF1 is separated from the plurality of light emitting elements LE. After UV or heat is applied to the first support film SPF1 to reduce the adhesive strength of the adhesive layer of the first support film SPF1, the first support film SPF1 may be physically or naturally separated. Next, the first transfer film LFL1 is stretched (1^{st} ORI). The first transfer film LFL1 may be stretched two-dimensionally in the first direction DR1 and the second direction DR2.

Since the first transfer film LFL1 is stretched, a separation distance between the plurality of light emitting elements LE attached onto the first transfer film LFL1 may be the second interval D2 larger than the first interval D1 of FIG. 21. Accordingly, the plurality of light emitting elements LE may be disposed in a dot shape at the second interval D2 on the first transfer film LFL1.

The stretching strength (or tensile strength) of the first transfer film LFL1 may be adjusted according to a desired separation distance between the light emitting elements LE, and may be, for example, about 120 gf/inch. However, the present disclosure is not limited thereto.

The present embodiment has described an example in which one stretching process is performed, but is not limited thereto. The stretching process may be performed a plurality of times.

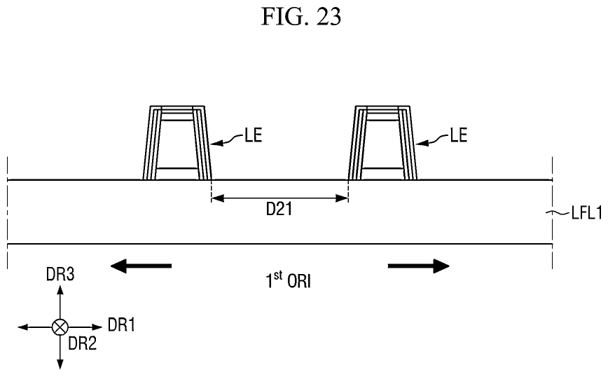

Next, referring to FIG. 23, the first transfer film LFL1 is bonded to the first substrate 110 and the plurality of light emitting elements LE are adhered onto the first and second pixel electrodes PE1 and PE2.

Specifically, the first transfer film LFL1 is aligned on the first substrate 110. In this case, the connection electrode 150 of the light emitting element LE formed on the first transfer film LFL1 is aligned to face the first substrate 110. As illustrated in FIG. 6, the first substrate 110 may have a plurality of pixel electrodes PE1 and PE2 formed thereon.

Next, the first substrate 110 and the first transfer film LFL1 are bonded together. Specifically, the connection electrode 150 of the light emitting element LE formed on the first transfer film LFL1 is brought into contact with the pixel electrodes PE1 and PE2 of the first substrate 110. In this case, the connection electrode 150 of the light emitting element LE is brought into contact with the pixel electrodes PE1 and PE2. Subsequently, the first substrate 110 and the first transfer film LFL1 are bonded by fusion bonding the connection electrode 150 of the light emitting element LE and the pixel electrodes PE1 and PE2. The plurality of light emitting elements LE are adhered to the top surfaces of the pixel electrodes PE1 and PE2.

In the fusion bonding, laser may be irradiated to the pixel electrodes PE1 and PE2 from a position above the second support film SPF2. High heat of the laser may be transferred to the pixel electrodes PE1 and PE2 irradiated with the laser, so that the interfaces between the connection electrode 150 of the light emitting element LE and the pixel electrodes PE1 and PE2 may be adhered. In particular, the pixel electrodes PE1 and PE2 may include copper (Cu) having excellent heat conduction and may have excellent adhesive properties with respect to the connection electrode 150 of the light emitting element LE. YAG may be used as the source of the laser used for fusion bonding.

In this case, even if the center of the array of the light emitting elements LE is shifted from the center of the pixel electrode PE1 without coinciding therewith, it is possible to minimize the phenomenon in which the light emitting element LE collapses from the pixel electrode PE1 because the width of the light emitting element LE is greater than the width of the pixel electrode PE1.

Then, the third semiconductor layer USE may be removed by ashing. A part of the third semiconductor layer USE may be left.

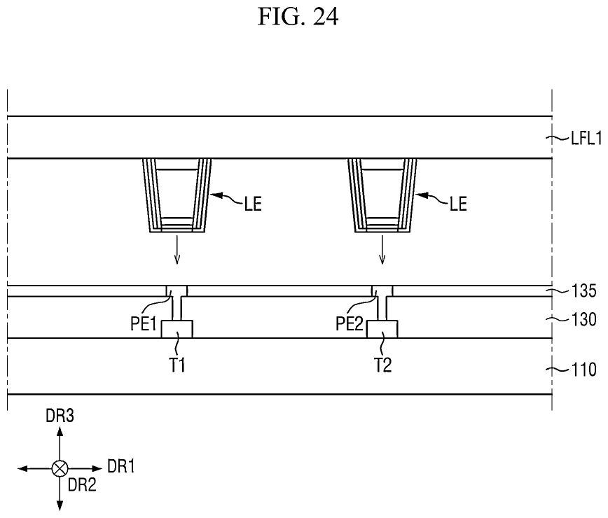

Next, referring to FIG. 24, the planarization layer PLL and the common electrode CE are formed on the first substrate 110 on which the light emitting elements LE are formed.

Specifically, the planarization layer PLL may be formed on a plurality of pixel electrodes PE1 and PE2. The planarization layers PLL may be disposed on the respective emission areas, and may be disposed to be spaced apart from each other on the adjacent emission areas. The planarization layer PLL may be formed by applying it using a solution process, such as spin coating or inkjet printing, and patterning it through an exposure process. The planarization layer PLL may be formed to the height of the light emitting element LE, but is not limited thereto.

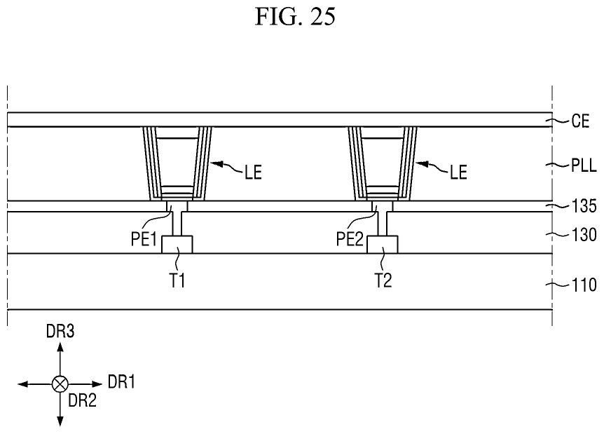

Then, referring to FIG. 25, the common electrode CE is formed on the light emitting element LE and the planarization layer PLL. The common electrode CE is continuously formed in the entire display area. The common electrode CE covers the planarization layer PLL and the light emitting element LE, and is in direct contact with them. The common electrode CE is formed by being in direct contact with the top surface of the second semiconductor layer SEM2 of the light emitting element LE.

Then, as illustrated in FIG. 6, the display device 10 according to an embodiment is manufactured by forming a wavelength control layer, a color filter layer, and the like.

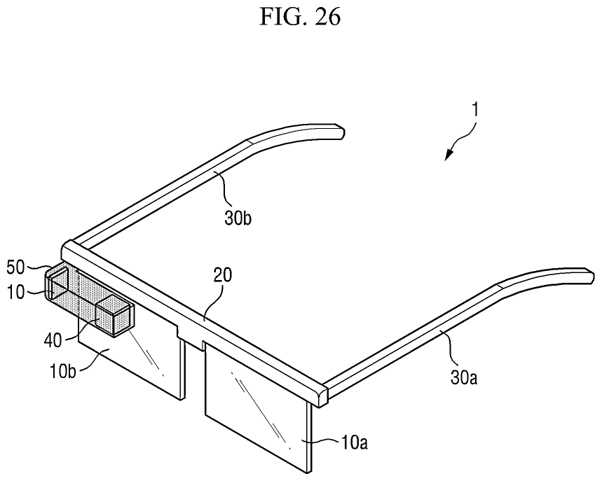

FIG. 26 is an example diagram illustrating a virtual reality device including a display device according to an embodiment. FIG. 26 illustrates a virtual reality device 1 in which the display device 10 according to an embodiment is used.

Referring to FIG. 26, the virtual reality device 1 according to an embodiment may be a device in a form of glasses. The virtual reality device 1 according to an embodiment may include a display device 10, a left-eye lens 10a, a right-eye lens 10b, a support frame 20, left and right legs 30a and 30b, a reflective member 40, and a display device housing 50.

FIG. 26 illustrates the virtual reality device 1 including the two legs 30a and 30b. However, the disclosure is not limited thereto. The virtual reality device 1 according to an embodiment may be used in a head-mounted display including a head-mounted band that may be mounted on a head instead of the legs 30a and 30b. For example, the virtual reality device 1 according to an embodiment is not limited to the example shown in FIG. 26, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 26 illustrates that the display device housing 50 is disposed at a right end of the support frame 20. However, an embodiment of the disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

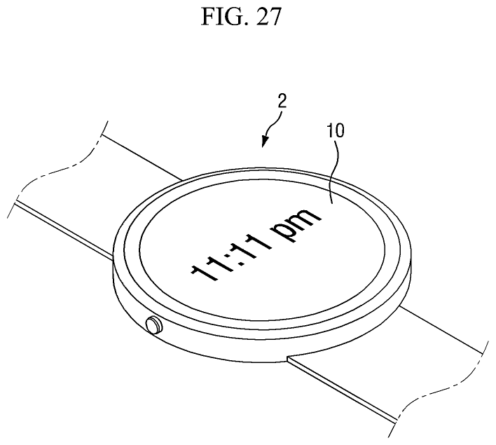

FIG. 27 is an example diagram illustrating a smart device including a display device according to an embodiment.

Referring to FIG. 27, a display device 10 according to an embodiment may be applied to a smart watch 2 as one of several smart devices.

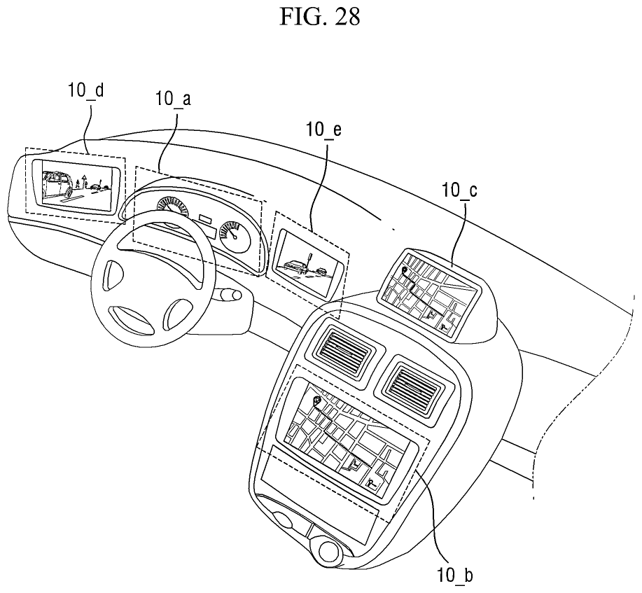

FIG. 28 is an example diagram illustrating a vehicle including a display device according to an embodiment. FIG. 28 illustrates a vehicle in which display devices according to an embodiment are used.

Referring to FIG. 28, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to each room mirror display that replaces each of side-view mirrors of the vehicle.

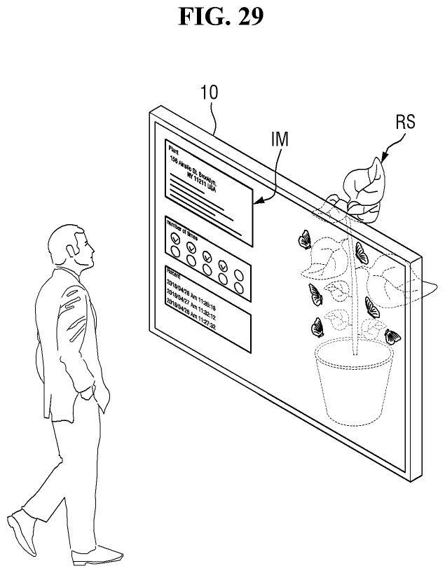

FIG. 29 is an example diagram illustrating a transparent display device including a display device according to an embodiment.

Referring to FIG. 29, a display device according to an embodiment may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the first substrate 110 of the display device 10 shown in FIG. 6 may include a light transmitting portion that may transmit light therethrough or may be made of a material that may transmit light therethrough.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a substrate;
a plurality of pixel electrodes disposed on the substrate and spaced apart from each other at a first interval; and
a plurality of light emitting elements respectively disposed on the plurality of pixel electrodes,
wherein each of the pixel electrodes has a rectangular shape having a long side and a short side, and
a width of each of the light emitting elements is larger than a width of the short side and smaller than the first interval between the pixel electrodes.

2. The display device of claim 1, wherein each of the light emitting elements comprises a second semiconductor layer; an active layer disposed on the second semiconductor layer; and a first semiconductor layer disposed on the active layer, and
a width of the first semiconductor layer is larger than the width of the short side and smaller than the first interval between the pixel electrodes.

3. The display device of claim 2, wherein each of the light emitting elements further comprises a connection electrode disposed on the first semiconductor layer and connected to a corresponding one of the pixel electrodes, and
a width of the connection electrode is larger than the width of the short side of the one pixel electrode and smaller than the first interval between the pixel electrodes.

4. The display device of claim 1, wherein the width of each of the light emitting elements ranges from 8 μm to 16 μm.

5. The display device of claim 4, wherein a length of the short side of one of the pixel electrodes ranges from 6 μm to 8 μm,
a length of the long side of the one pixel electrode ranges from 45 μm to 55 μm, and
the first interval ranges from 16 μm to 19 μm.

6. The display device of claim 5, further comprising a first planarization layer disposed between the pixel electrodes on the substrate.

7. The display device of claim 6, wherein the one pixel electrode comprises a pixel reflective layer disposed to contact one of the light emitting elements.

8. The display device of claim 7, wherein the pixel reflective layer has a reflectivity of 80% or more.

9. The display device of claim 3, wherein the number of the light emitting elements disposed on the one pixel electrode is three,
the light emitting elements disposed on the one pixel electrode are spaced apart from each other at a second interval, and
the second interval ranges from 10 μm to 20 μm.

10. The display device of claim 3, wherein the number of the light emitting elements disposed on the one pixel electrode is two,
the light emitting elements disposed on the one pixel electrode are spaced apart from each other at a second interval, and
the second interval ranges from 15 μm to 20 μm.

11. The display device of claim 3, wherein the number of light emitting elements disposed on the one pixel electrode is four,
the light emitting elements disposed on the one pixel electrode are spaced apart from each other at a second interval, and
the second interval ranges from 10 μm to 15 μm.

12. The display device of claim 6, further comprising:
a second planarization layer disposed on the first planarization layer and disposed between the light emitting elements; and
a common electrode disposed on the second planarization layer and the light emitting elements; and
a wavelength converter disposed on the common electrode,
wherein the wavelength converter comprises:
a partition wall partitioning emission areas and a non-emission area;
a wavelength conversion layer disposed between the partition walls and overlapping the emission areas;
a light blocking member disposed on the partition wall; and
color filters disposed on the wavelength conversion layer,
wherein the light blocking member does not overlap the one pixel electrode.

13. A display device comprising:
a substrate;
a plurality of pixel electrodes disposed on the substrate and spaced apart from each other at a first interval; and
a plurality of light emitting elements respectively disposed on the plurality of pixel electrodes,
wherein each of the pixel electrodes has a rectangular shape having a long side and a short side,
a width of each of the light emitting elements is larger than a width of the short side, and
a ratio of a length of the short side to the first interval is 1:1.7 to 1:1.8.

14. The display device of claim 13, wherein each of the light emitting elements comprises a second semiconductor layer; an active layer disposed on the second semiconductor layer; and a first semiconductor layer disposed on the active layer, and
a width of the first semiconductor layer is larger than the width of the short side and smaller than the first interval between the pixel electrodes.

15. The display device of claim 14, wherein each of the light emitting elements further comprises a connection electrode disposed on the first semiconductor layer and connected to a corresponding one of the pixel electrodes, and
a width of the connection electrode is larger than the width of the short side of the one pixel electrode and smaller than the first interval between the pixel electrodes.

16. The display device of claim 15, wherein the width of each of the light emitting elements ranges from 8 μm to 16 μm,
a length of the short side of the one pixel electrode ranges from 6 μm to 8 μm,
a length of the long side of the one pixel electrode ranges from 45 μm to 55 μm, and
the first interval ranges from 16 μm to 19 μm.

17. The display device of claim 16, further comprising a first planarization layer disposed between the pixel electrodes on the substrate.

18. The display device of claim 15, wherein the number of the light emitting elements disposed on the one pixel electrode is three,
the light emitting elements disposed on the one pixel electrode are spaced apart from each other at a second interval, and
the second interval ranges from 10 μm to 20 μm.

19. The display device of claim 15, wherein the number of light emitting elements disposed on the one pixel electrode is two,
the light emitting elements disposed on the one pixel electrode are spaced apart from each other at a second interval, and
the second interval ranges from 15 μm to 20 μm.

20. The display device of claim 15, wherein the number of light emitting elements disposed on the one pixel electrode is four,
the light emitting elements disposed on the one pixel electrode are spaced apart from each other at a second interval, and
the second interval ranges from 10 μm to 15 μm.
